(19) United States
(12) Patent Application Publication
(10) Pub. No.: US 2025/0107086 A1
(43) Pub. Date: Mar. 27, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Hanbyeol LEE, Suwon-si (KR); Younghwan SON, Suwon-si (KR); Sangdon LEE, Suwon-si (KR); Shinhwan KANG, Suwon-si (KR); Sukkang SUNG, Suwon-si (KR)

(73) Assignee: Samsung Electronics Co., Ltd., Suwon-si (KR)

(21) Appl. No.: 18/737,295

(22) Filed: Jun. 7, 2024

(30) Foreign Application Priority Data
Sep. 27, 2023 (KR) 10-2023-0130508

(51) Int. Cl. H10B 43/27; H01L 23/00; H01L 25/065; H01L 25/18; H10B 41/27; H10B 41/35; H10B 43/35; H10B 80/00

(52) U.S. Cl. CPC H10B 43/27; H01L 24/08; H01L 25/0657; H01L 25/18; H10B 41/27; H10B 41/35; H10B 43/35; H10B 80/00; H01L 2224/08145; H01L 2924/1431; H01L 2924/14511

(57) ABSTRACT

A semiconductor device includes gate electrodes stacked and spaced apart from each other including upper gate electrodes, memory gate electrodes and lower gate electrodes sequentially stacked from the horizontal conductive layer; a horizontal connection portion between the memory gate electrodes and the lower gate electrodes; channel structures penetrating through the gate electrodes and extending in the first direction in the first region; isolation regions penetrating through the gate electrodes; an insulating region extending from a lowermost surface of the gate electrodes and penetrating through at least one of the lower gate electrodes between the isolation regions; wherein an upper surface of the insulating region has a first width, a lower surface has a second width greater than the first width, an upper surface of each of the channel structures has a third width, and a lower surface has a fourth width smaller than the third width.

### CROSS-REFERENCE TO RELATED APPLICATION(S)

This application claims benefit of priority to Korean Patent Application No. 10-2023-0130508 filed on Sep. 27, 2023 in the Korean Intellectual Property Office, the disclosure of which is incorporated herein by reference in its entirety.

### BACKGROUND

Various example embodiments relate to a semiconductor device and a data storage system including the same.

A semiconductor device able to store high-capacity data in a data storage system requiring data storage has been necessary. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

Various example embodiments may provide a semiconductor device having improved reliability.

Alternatively or additionally, various example embodiments may provide a data storage system including a semiconductor device having a semiconductor device having improved reliability.

According to some example embodiments, a semiconductor device includes a first semiconductor structure including a substrate, circuit devices on the substrate, and circuit interconnection lines on the circuit devices; and a second semiconductor structure on the first semiconductor structure and having a first region and a second region, the second semiconductor structure including a horizontal conductive layer; gate electrodes stacked and spaced apart from each other in a first direction perpendicular to a lower surface of the horizontal conductive layer below the horizontal conductive layer, and including upper gate electrodes, memory gate electrodes, and lower gate electrodes, the upper gate electrodes, memory gate electrodes, and lower gate electrodes sequentially stacked from the horizontal conductive layer; a horizontal connection portion between the memory gate electrodes and the lower gate electrodes; channel structures penetrating through the gate electrodes and extending in the first direction in the first region; isolation regions penetrating through the gate electrodes, extending in the first direction and in a second direction perpendicular to the first direction, and spaced apart from each other in a third direction perpendicular to the first and second directions; an insulating region extending from a lowermost surface of the gate electrodes and penetrating through at least one of the lower gate electrodes between the isolation regions; and second bonding metal layers below the gate electrodes and connected to the first bonding metal layers an upper surface of the insulating region having a first width, and a lower surface of the insulating region having a second width greater than the first width, an upper surface of each of the channel structures having a third width, and a lower surface of each of the channel structures having a fourth width smaller than the third width.

Alternatively or additionally according to various example embodiments, a semiconductor device includes a horizontal conductive layer; gate electrodes stacked and spaced apart from each other below the horizontal conductive layer in a first direction perpendicular to a lower surface of the horizontal conductive layer, and including upper gate electrodes, memory gate electrodes, and lower gate electrodes sequentially stacked from the horizontal conductive layer; a horizontal connection portion between the memory gate electrodes and the lower gate electrode; channel structures including a first channel portion penetrating through the lower gate electrode and extending in the first direction, a connection channel portion penetrating through the horizontal connection portion and connected to the first channel portion, and a second channel portion penetrating through the memory gate electrodes and upper gate electrodes and connected to the connection channel portion, and further including a channel layer connected to the first channel portion, the connection channel portion, and the second channel portion; isolation regions penetrating through the gate electrodes and extending in the first direction and in a second direction perpendicular to the first direction, and spaced apart from each other in a third direction perpendicular to the first and second directions; and an insulating region extending from a lowermost surface of the gate electrodes and penetrating through at least one of the lower gate electrodes between the isolation regions, wherein a width of a lower surface of the insulating region is greater than a width of an upper surface of the insulating region, a width of a lower surface of the first channel portion is smaller than a width of an upper surface of the first channel portion, a width of a lower surface of the connection channel portion is smaller than a width of an upper surface of the connection channel portion, and a width of a lower surface of the second channel portion is smaller than a width of an upper surface of the second channel portion.

Alternatively or additionally according to various example embodiments, a data storage system includes a semiconductor storage device including a first semiconductor structure including circuit devices, a second semiconductor structure on one surface of the first semiconductor structure, and an input/output pad electrically connected to the circuit devices; and a controller electrically connected to the semiconductor storage device through the input/output pad and configured to control the semiconductor storage device, wherein the second semiconductor structure includes a horizontal conductive layer; gate electrodes stacked and spaced apart from each other below the horizontal conductive layer in a first direction perpendicular to a lower surface of the horizontal conductive layer, and including upper gate electrodes, memory gate electrodes and lower gate electrodes sequentially stacked from the horizontal conductive layer; a horizontal connection portion between the memory gate electrodes and the lower gate electrodes; channel structures penetrating through the gate electrodes and extending in the first direction in the first region; isolation regions penetrating through the gate electrodes and extending in the first direction and a second direction perpendicular to the first direction, and spaced apart from each other in a third direction perpendicular to the first and second directions; an insulating region extending from a lowermost surface of the gate electrodes and penetrating through at least one of the lower gate electrodes between the isolation regions; and second bonding metal layers below the gate electrodes and connected to the first bonding metal layers, wherein an upper surface of the insulating region has a first width, a lower surface of the insulating region has a second width greater than the first width, and an upper surface of each of the channel structures has a third width, and a lower surface of each of the channel structures has a fourth width less than the third width.

### BRIEF DESCRIPTION OF DRAWINGS

The above and other aspects, features, and advantages of various example embodiments will be more clearly understood from the following detailed description, taken in combination with the accompanying drawings, in which:

FIG. 1A are 1B are plan views illustrating a semiconductor device according to some example embodiments;

FIGS. 2A and 2B are cross-sectional views illustrating a semiconductor device according to some example embodiments;

FIGS. 3A to 3C are enlarged views illustrating a portion of a semiconductor device according to some example embodiments;

FIGS. 4 to 6 are cross-sectional views illustrating a semiconductor device according to some example embodiments;

FIGS. 7A to 7L are cross-sectional views illustrating a method of manufacturing a semiconductor device according to some example embodiments;

FIG. 8 is a diagram illustrating a data storage system including a semiconductor device according to some example embodiments;

FIG. 9 is a perspective views illustrating a data storage system including a semiconductor device according to some example embodiments; and

FIG. 10 is a cross-sectional views illustrating a semiconductor package according to some example embodiments.

### DETAILED DESCRIPTION

Hereinafter, various example embodiments will be described as follows with reference to the accompanying drawings.

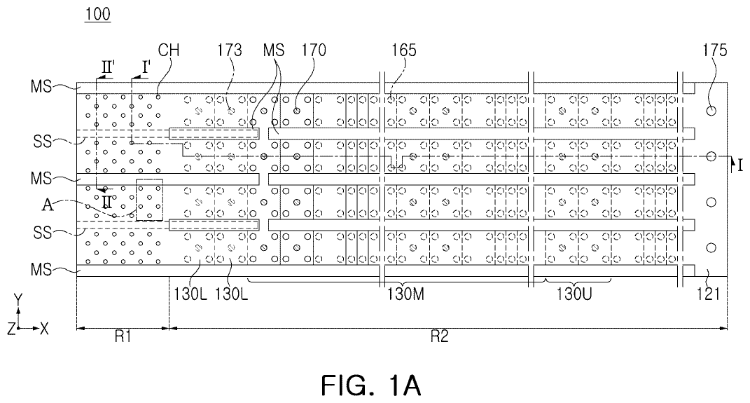

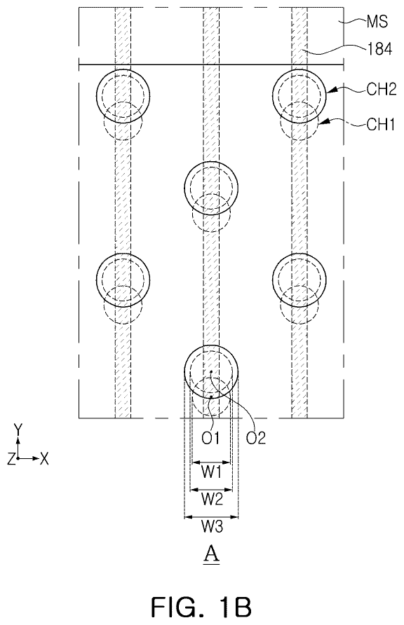

FIGS. 1A are 1B are plan views illustrating a semiconductor device according to an example embodiment, and FIG. 1B shows an enlarged view of area “A” in FIG. 1A.

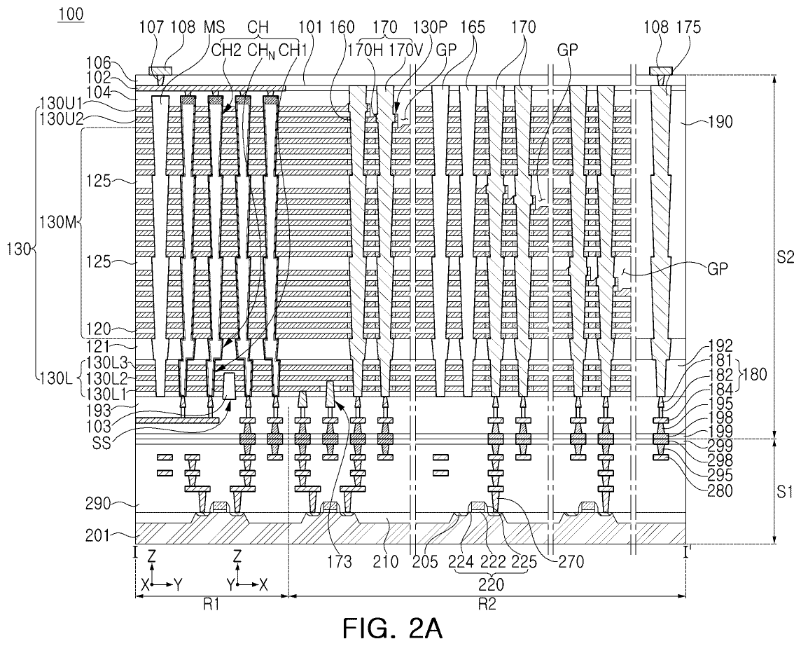

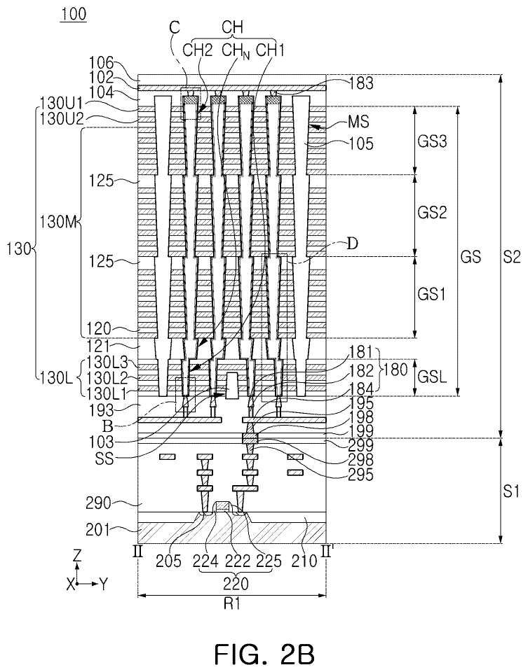

FIGS. 2A and 2B are cross-sectional views illustrating a semiconductor device according to some example embodiments, taken along lines I-I′ and II-II′ in FIG. 1A.

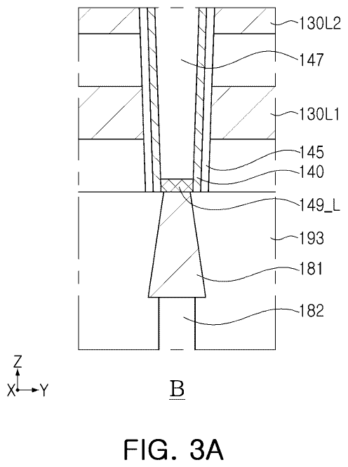

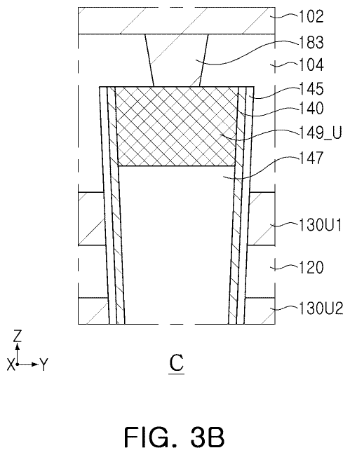

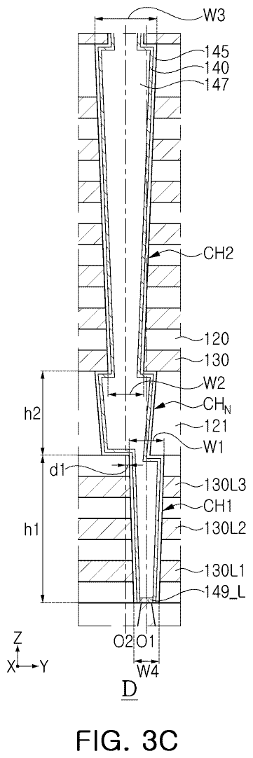

FIGS. 3A to 3C are enlarged views illustrating a portion of a semiconductor device according to various example embodiments. FIG. 3A is an enlarged view of area “B” in FIG. 2B, FIG. 3B is an enlarged view of area “C” in FIG. 2B, and FIG. 3C is an enlarged view of area “D” in FIG. 2B.

Referring to FIGS. 1A to 3C, a semiconductor device 100 may include first and second structures S1 and S2 stacked vertically. For example, the first structure S1 may include a peripheral circuit region PERI of the semiconductor device 100, and the second structure S2 may include a memory cell region CELL of the semiconductor device 100. The semiconductor device 100 may be or may include or be included in a cell-over-periphery (COP) structure.

The first structure S1 may include a substrate 201, source/drain regions 205 and device isolation layers 210 in the substrate 201, circuit devices 220 disposed on the substrate 201, circuit contact plugs 270, circuit interconnection lines 280, a peripheral region insulating layer 290, first bonding vias 295, and first bonding metal layers 298.

The substrate 201 may have an upper surface extending in the X-direction and the Y-direction. The device isolation layers 210 may be formed on the substrate 201 such that an active region may be defined. The source/drain regions 205 including impurities may be disposed in a portion of the active region. The substrate 201 may include a semiconductor material, such as a group IV semiconductor, a group III-V compound semiconductor, or a group II-VI compound semiconductor. For example, the substrate 201 may be provided as a single crystal bulk wafer or a single crystal chip.

The circuit devices 220 may include transistors such as NMOS and/or CMOS transistors, which may be implemented as or embodied as planar transistors and/or three-dimensional transistors. Each of the circuit devices 220 may include a circuit gate dielectric layer 222, spacer layers 224 and circuit gate electrode 225. The source/drain regions 205 may be disposed in the substrate 201 on both sides of the circuit gate electrode 225. In some example embodiments, at least one circuit gate electrode 225 may extend in a first horizontal direction (an X direction); alternatively or additionally, at least one circuit gate electrode 225 may extend in a second horizontal direction (a Y direction).

The peripheral region insulating layer 290 may be disposed on the circuit device 220 on the substrate 201. Circuit contact plugs 270 and peripheral region insulating layer 290 may form the first interconnection structure of the first structure S1. The circuit contact plugs 270 may have a cylindrical shape and may penetrate through the peripheral region insulating layer 290 and may be connected to the source/drain regions 205. An electrical signal may be applied to the circuit device 220 through the circuit contact plugs 270. In a region not illustrated, circuit contact plugs 270 may also be connected to the circuit gate electrode 225. The circuit interconnection lines 280 may be connected to the circuit contact plugs 270, may have a line shape, and may be disposed in a plurality of layers. In some example embodiments, the number of layers of the circuit contact plugs 270 and/or the circuit interconnection lines 280 and/or the orientations and/or spacings and/or thicknesses thereof may be varied.

The first bonding vias 295 and the first bonding metal layers 298 may be included in the first bonding structure and may be disposed on a portion of the uppermost circuit interconnection lines 280. The first bonding vias 295 may have a cylindrical shape, and the first bonding metal layers 298 may have a line shape. Upper surfaces of the first bonding metal layers 298 may be exposed to an upper surface of the first structure S1. The first bonding vias 295 and the first bonding metal layers 298 may be or may function as a bonding structure or a bonding layer of the first structure S1 and the second structure S2. In some example embodiments, the first bonding vias 295 and the first bonding metal layers 298 may provide an electrical connection path with the second structure S2. In some example embodiments, a portion of the first bonding metal layers 298 may not be connected to the lower circuit interconnection lines 280 and may be disposed only for bonding. The first bonding vias 295 and the first bonding metal layers 298 may include the same and/or different conductive materials, for example, copper (Cu).

In some example embodiments, the peripheral region insulating layer 290 may include a bonding insulating layer 299 having a thickness such as a predetermined thickness from an upper surface. The bonding insulating layer 299 may be provided for dielectric-dielectric bonding with the bonding insulating layer 299 of the second structure S2. The bonding insulating layer 299 may also be or function as a diffusion barrier of the first bonding metal layers 298 and, for example, may include at least one of SiO, SiN, SiCN, SiOC, SiON, and SiOCN.

The second structure S2 may include a horizontal conductive layer 102 having a first region R1, gate electrodes 130 stacked and spaced apart from each other in the Z-direction on a lower surface of the horizontal conductive layer 102 and forming the gate structure GS, interlayer insulating layers 120 alternately stacked with the gate electrodes 130, a first channel portion CH1 disposed to penetrate through the gate structure GS in the first region R1, channel structures CH including a connection channel portion CH_{N} and a second channel portion CH2, isolation regions MS penetrating through the gate electrodes 130 and extending in one direction, and lower insulating regions SS penetrating through a portion of the gate electrodes 130. The second structure S2 may further include a horizontal insulating layer 101 disposed in parallel with the horizontal conductive layer 102 in the second region R2, and a passivation layer 106 disposed on the cell region insulating layer 190 and covering the gate electrodes 130. The second structure S2 may further include support structures 165, contact plugs 170, through-vias 175 and cell interconnection lines 180. The second structure S2 may further include second bonding vias 195 and second bonding metal layers 198 as a second bonding structure.

In the second structure S2, which includes or is included in a memory cell region, in the first region R1, the gate electrodes 130 may be vertically stacked and the channel structures CH may be disposed, and memory cells may be disposed in the first region R1. In the second region R2, the gate electrodes 130 may extend to different lengths, and may be configured to electrically connect the memory cells to the first structure S1. The second region R2 may be disposed at least in one direction, for example at least one end of the first region R1 in the X-direction.

The horizontal conductive layer 102 may have an upper surface extending in the X-direction and the Y-direction. The horizontal conductive layer 102 may include a conductive material. For example, the horizontal conductive layer 102 may include a semiconductor material, such as a group IV semiconductor, a group III-V compound semiconductor, or a group II-VI compound semiconductor. For example, a group IV semiconductor may include silicon, germanium, or silicon-germanium. The horizontal conductive layer 102 may be or may include a dopped layer; example embodiments are not limited thereto. The horizontal conductive layer 102 may be provided as a semiconductor layer, such as a polycrystalline silicon layer, or an epitaxial layer. The horizontal conductive layer 102 may be or may function as a portion of a common source line CSL of the semiconductor device 100 and may be formed as a multilayer structure, but example embodiments are not limited thereto. The horizontal conductive layer 102 may be connected through upper channel pads 149_U and upper studs 183 of the channel structures CH.

The horizontal insulating layer 101 may be disposed parallel to the horizontal conductive layer 102 in at least a portion of the second region R2. The horizontal insulating layer 101 may be layers remaining after a portion is formed as the horizontal conductive layer 102 in a process of manufacturing the semiconductor device 100, but example embodiments are not limited thereto. The horizontal insulating layer 101 may include one or more of silicon oxide, silicon nitride, silicon carbide, or silicon oxynitride.

The substrate insulating layer 192 may be disposed in a region in which the through-via 175 extending from the second structure S2 to the first structure S1 is disposed in a portion of the second region R2. An upper surface of the substrate insulating layer 192 may be coplanar with an upper surface of the lower gate structure GS_L. The substrate insulating layer 192 may include an insulating material, for example, one or more of silicon oxide, silicon nitride, silicon carbide, or silicon oxynitride.

The gate structure GS may include first, second, and third gate structures GS1, GS2, and GS3 vertically stacked. In some example embodiments, the number of gate structures forming the gate structure GS may be varied. For example, in some example embodiments, the gate structure GS may include four or more gate structures or may include a single gate structure. The number of gate electrodes 130 forming each of the first to third gate structures GS1-GS3 may be the same or different (e.g., at least one may be greater than or less than at least one other).

The gate structure GS may further include a lower gate structure GSL below the first to third gate structures GS1-GS3. The lower gate structure GSL may include a smaller number of gate electrodes 130L than the number of gate electrodes 130 forming each of the first to third gate structures GS1-GS3. As an example, three to seven gate electrodes 130L may be included, but example embodiments are not limited thereto.

The gate electrodes 130 may include lower gate electrodes 130L1 and 130L2 forming string selection transistors, memory gate electrodes 130M forming a plurality of memory cells, and upper gate electrodes 130U forming an erase transistor and a ground selection transistor. The number of memory gate electrodes 130M included in the memory cells may be a factor in determining the capacity of the semiconductor device 100. One of the upper gate electrodes 130U and the lower gate electrodes 130L may also be referred to as upper selection gate electrode and a lower selection gate electrode. In some example embodiments, each of the number of the upper gate electrode 130U and the number of the lower gate electrodes 130L may each be one to four or more, and the number of the lower gate electrodes 130L may be seven or more. The upper gate electrode 130U and the lower gate electrodes 130L may have a structure the same as or different from that of the memory gate electrodes 130M. In some example embodiments, the upper gate electrode 130U and/or at least one lower gate electrode 130L may not be provided. A portion of the gate electrodes 130, for example, the upper gate electrode 130U or the memory gate electrodes 130M adjacent to the lower gate electrodes 130L, may be dummy gate electrodes, and at least one of the lower gate electrodes 130L may be dummy gate electrodes 130L3.

The gate electrodes 130 may be vertically stacked and spaced apart from each other on the first region R1, may extend at different lengths from the first region R1 to the second region R2 and may form step structures having a staircase shape in the gate pad regions GP. As illustrated in FIG. 2A, the gate electrodes 130 may be removed to a predetermined depth from an upper portion of one of the first to third gate structures GS1, GS2, and GS3 in the gate pad regions GP. The gate pad regions GP may be disposed such that the gate pad regions GP may not overlap each other in the Z-direction. At least a portion of the gate electrodes 130 forming the upper second gate structures GS2 may extend horizontally on the gate pad region GP of the first gate structure GS1. In various example embodiments, the gate pad regions GP may be disposed in the third gate structure GS3, the second gate structure GS2, and the first gate structure GS1 in order in the X-direction from the first region R1. In some example embodiments, the arrangement form, the arrangement order, and the depth of the gate pad regions GP may be varied. In some example embodiments, the gate electrodes 130 may not be disposed on the gate pad regions GP.

The gate electrodes 130 may form first to third step structures in an asymmetric form in the X-direction in each of the gate pad regions GP. The first step structure may be configured as a staircase structure relatively adjacent to first region R1 and having a level decreasing in the X-direction, and the second step structure may be configured as a staircase structure disposed relatively far from the first region R1 and having a level increasing in the X-direction. For example, in each of the gate pad regions GP, a slope of the first step structure may be smaller than a slope of the second step structure in the first region R1. In some example embodiments, the first and second step structures may have symmetrical forms. In the first step structure, the gate electrodes 130 may be connected to contact plugs 170, and in the second step structure, the gate electrodes 130 may form a dummy region or a support structure not connected to the contact plugs 170. In some example embodiments, a specific shape of the step structure, and/or the number of the gate electrodes 130 forming each step structure are not limited to the example illustrated in FIG. 2A. In some example embodiments, the gate electrodes 130 may be disposed to have a step structure with respect to each other in the Y-direction.

As illustrated in FIG. 2A, due to the first step structure, the lower gate electrode 130L of the gate electrodes 130 may extend longer than the upper gate electrode 130, such that each of the gate electrodes 130 may have contact regions 130P exposed upwardly from the interlayer insulating layers 120. The gate electrodes 130 may be connected to the contact plugs 170 in the contact regions 130P, which are end regions, respectively. Gate electrodes 130, excluding the lower gate electrode 130L, may have an increased thickness in the contact regions 130P. A thickness of the gate electrodes 130 in the contact region 130P may be greater than a thickness in a region in which the other gate electrodes 130 are disposed on an upper surface, including the first region R1.

The gate electrodes 130, including the lower gate electrodes 130L, may include a metal material, such as tungsten (W). In some example embodiments, the gate electrodes 130 may include polycrystalline silicon or metal silicide materials. The entirety of the gate electrodes 130 may include the same material; however, example embodiments are not limited thereto. In some example embodiments, the gate electrodes 130 may further include a diffusion barrier, for example, the diffusion barrier may include tungsten nitride (WN), tantalum nitride (TaN), titanium nitride (TiN), or a combination thereof.

The interlayer insulating layers 120 may be disposed between the gate electrodes 130. Similarly to the gate electrodes 130, the interlayer insulating layers 120 may be disposed to be spaced apart from each other in a direction perpendicular to the lower surface of the horizontal conductive layer 102 and to extend in the X-direction. The interlayer insulating layers 120 may include an insulating material such as silicon oxide and/or silicon nitride. Among the interlayer insulating layers 120, the interlayer insulating layer 125 between the gate structure GS1-GS3 may have a thickness greater than that of the other interlayer insulating layers 120.

A horizontal connection portion 121 may be further included between the first gate structure GS1 and the lower gate structure GSL. The horizontal connection portion 121 may include at least one lower interlayer insulating layer 121. The horizontal connection portion 121 may have a thickness greater than that of the interlayer insulating layers 120 and may have a thickness greater than that of the interlayer insulating layer 125 between the gate structures GS1-GS3. As an example, the horizontal connection portion 121 may have a thickness which may be 7 to 10 times that of the gate electrode 130. When the horizontal connection portion 121 includes the lower interlayer insulating layer 121, the lower interlayer insulating layer 121 may include an insulating material such as silicon oxide.

Each of the channel structures CH may form or may correspond to a memory cell string, and may be spaced apart from each other in rows and columns below the horizontal conductive layer 102 in the first region R1. The channel structures CH may be disposed to form a grid pattern on the X-Y plane or a zigzag pattern in one direction. The channel structures CH may have a pillar shape, and a width thereof may taper or decrease in a direction away from the horizontal conductive layer 102 depending on an aspect ratio, and may have a sloped side surface. In some example embodiments, at least a portion of the channel structures CH disposed on an end of the first region R1 may be dummy channel structures.

As illustrated in FIG. 3C, each of the channel structures CH may include a first channel portion CH1, a connection channel portion CH_{N}, and a second channel portions CH2 vertically stacked. The second channel portion CH2 may include a first sub-channel portion, a second sub-channel portion and third sub-channel portions CHa, CHb, and CHc penetrating through the first to third gate structures GS1, GS2, and GS3 of the gate structure GS, respectively. In the second channel portion CH2, the first sub-channel portion CHa and the second sub-channel portion CHb disposed thereon may be connected to each other, and the second sub-channel portion CHb and the third sub-channel portion CHc disposed thereon may be connected to each other. In the first to third sub-channel portions CHa, CHb, and CHc, a width W3 of an upper surface of the sub-channel portion disposed in a lower portion may be greater than a width W2 of a lower surface of the sub-channel portion disposed in an upper portion in regions connected to each other or on an interfacial surface. Accordingly, the second channel portion CH2 may have a shape in which the width W3 of the upper surface may be greater than the width W2 of the lower surface, and the width W3 of an upper surface of each of the first to third sub-channel portions CHa, CHb, and CHc may be greater than the width W2 of the lower surface. The second channel portion CH2 may have bent portions, which may be due to a difference in widths on an interfacial surface between the first to third sub-channel portions CHa, CHb, and CHc, and a width of each of the first to third sub-channel portions CHa, CHb, and CHc may decrease downwardly, that is, in a direction away from the horizontal conductive layer 102, such that a side surface thereof may have a slope. In some example embodiments, the number of the sub-channel portions CHa, CHb, and CHc stacked in the Z-direction in the second channel portion CH2 may be varied. The connection channel portion CH_{N} may be disposed in a lower portion of the first sub-channel portion CHa of the second channel portion CH2. The connection channel portion CH_{N} may penetrate through the horizontal connection portion 121, and the width W3 of the upper surface of the first sub-channel portion CHa may be greater than the width W2 of the lower surface disposed in an upper portion on an interfacial surface with the first sub-channel portion CHa and the width may decrease downwardly such that a side surface thereof may have a slope. A width of an upper surface of the connection channel portion CH_{N} may be equal to or smaller than the width W3 of the upper surface of the first to third sub-channel portions CHa, CHb, and CHc, but example embodiments are not limited thereto. The first channel portion CH1 may be disposed below the connection channel portion CH_{N}. The first channel portion CH1 may penetrate through the lower gate electrodes 130L1-130L3 of the lower gate structure GSL, and at least a portion of the connection channel portion disposed above the interfacial surface with CH_{N} may be offset in a horizontal direction from a lower surface of the connection channel portion CH_{N} disposed in an upper portion on an interfacial surface with the connection channel portion CH_{N} such that an upper surface may be disposed. That is, as illustrated in FIG. 3C, when the conceptual lines extending in the Z-direction along a center of the width of each channel portion CH1, CH2, and CH_{N} are referred to as central lines O1 and O2, the central line O2 of the second channel portion CH2 may not coincide the central line O1 of first channel portion CH1. For example, the central line O1 of the first channel portion CH1 may be shifted in the Y-direction with respect to the central line O2 of the second channel portion CH2, and may be spaced apart from the central line O2 of the second channel portion CH2 by a first distance d1 in the horizontal direction and may be offset such that an upper surface of the second channel portion CH2 may be disposed, and the first channel portion CH1 may not be disposed on the central line O2 of the second channel portion CH2. In this case, the central line of the connection channel portion CH_{N} may coincide with or be collinear with the central line O2 of the second channel portion CH2, but example embodiments are not limited thereto. For example, the central line O2 of the second channel portion CH2 and the connection channel portion CH_{N} may coincide, and the central line O1 of the first channel portion CH1 may be offset in the horizontal direction (Y-direction). Accordingly, a lower surface of the connection channel portion CH_{N} may be exposed to the lower gate electrodes 130L1-130L3, and a spacing in which the first channel portions CH1 is not disposed may be present toward a lower portion of the connection channel portions CH_{N} between adjacent channel structures CH. For example, the first channel portions CH1 of the two channel structures CH on both sides may be offset in opposite directions with respect to the lower insulating region SS, and a spacing in which the lower insulating region SS may be formed between the first channel portions CH1 may be assured.

A width W1 of an upper surface of the first channel portion CH1 may be equal to or smaller than the width W2 of the lower surface of the first sub-channel portion CHa, and the width may decrease downwardly, e.g., in a direction away from the horizontal conductive layer 102 such that a side surface thereof may have a slope, and the width W4 of the lower surface may be the smallest. An end of the first channel portion CH1 may penetrate through the lowermost gate electrode 130L1 of the lower gate electrodes 130L1-130L3 and may protrude downwardly, may be connected to a lower stud 181 and may be connected to the interconnection structure. The first channel portion CH1, the connection channel portion CH_{N} and the second channel portion CH2 may be connected to each other and may form the channel structures CH.

Each of the channel structures CH may include a channel layer 140, a gate dielectric layer 145, a channel filling insulating layer 147, and channel pads 149 disposed in a channel hole. The channel layer 140, the gate dielectric layer 145, and the channel filling insulating layer 147 may be connected to each other between the first and second channel portions and the connection channel portions CH1, CH2, and CH_{N}.

As illustrated in the enlarged diagrams in FIGS. 3A to 3C, the channel layer 140 may be formed as an annular shape surrounding the internal channel filling insulating layer 147, or in some example embodiments, the channel layer 140 may have a pillar shape such as a cylinder or prism without the channel filling insulating layer 147. The channel layer 140 may be connected to the horizontal conductive layer 102 in an upper portion through the upper channel pad 149_U. The channel layer 140 may include a semiconductor material such as polycrystalline silicon or single crystalline silicon, and may or may not be doped.

The gate dielectric layer 145 may be disposed between the gate electrodes 130 and the channel layer 140. Although not specifically illustrated, the gate dielectric layer 145 may include at least one of a tunneling layer, a charge storage layer, and a blocking layer sequentially stacked from the channel layer 140. The tunneling layer may tunnel electric charges into the charge storage layer, and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), high-κ material having a dielectric constant greater than that of silicon oxide, or a combination thereof. In some example embodiments, at least a portion of the gate dielectric layer 145 may extend in the horizontal direction along the gate electrodes 130.

The channel pad 149 may include an upper channel pad 149_U disposed on the upper end of the second channel portion CH2 and a lower channel pad 149_L disposed on a lower end of the first channel portion CH1. The upper channel pad 149_U may have a greater thickness than that of the lower channel pad 149_L, but example embodiments are not limited thereto. The upper channel pad 149_U and the lower channel pad 149_L may include, for example, doped polycrystalline silicon.

The lower horizontal insulating layer 193 may be disposed below the channel structures CH and may extend horizontally in the first region R1 and the second region R2. The lower horizontal insulating layer 193 may include an insulating material, and the lower horizontal insulating layer 193 may include nitride, for example, at least one of SiN, SiON, SiCN, and SiOCN.

The isolation regions MS may penetrate through at least a portion of the gate electrodes 130 and may extend in the X-direction. As illustrated in FIG. 1A, the isolation regions MS may be disposed parallel to each other. As illustrated in FIG. 2B, the isolation regions MS may penetrate through gate electrodes 130 and may be connected to the lower horizontal insulating layer 193 therebelow.

A portion of the isolation regions MS may extend as a single region along the first region R1 and the second region R2, and the other portion may extend only to a portion of the second region R2, or may be disposed intermittently in the first region R1 and the second region R2. However, in some example embodiments, the arrangement form and the number of the isolation regions MS are not limited to the example illustrated in FIG. 1A.

A gate isolation insulating layer 105 may be disposed in each of the isolation regions MS. The gate isolation insulating layer 105 may have a shape of which a width may decrease toward the lower horizontal insulating layer 193 due to a high aspect ratio. The isolation regions MS may have a bent shape on an interfacial surface between the gate structures GS, and may also have a bent shape on an interfacial surface between the lower interlayer insulating layer 121 and the lower gate structures GSL. Accordingly, similarly to the channel structure CH, the isolation regions MS may include an inflection region in which a width of upper and lower surfaces thereof may change on an interfacial surface between the gate structure GS, but differently from the channel structure CH, a central line of a width of the isolation regions MS penetrating through the lower gate structure GSL and a central line of a width of the isolation regions MS penetrating the first to third gate structures GS1-GS3 may be the same. The gate isolation insulating layer 105 may include an insulating material, for example, silicon oxide, silicon nitride, or silicon oxynitride.

The lower insulating regions SS may extend in the X-direction between adjacent isolation regions MS, as illustrated in FIG. 1A. The lower insulating regions SS may be disposed in a portion of the second region R2 and in the first region R1. A side surface of the lower insulating regions SS may have a slope such that a width may increase downwardly in the Z-direction, that is, as in a direction away from the horizontal conductive layer 102. The lower insulating regions SS may have a slope direction opposite to a slope direction of the channel structures CH. In particular, the lower insulating regions SS may have a slope direction opposite to the slope directions of the first channel portion CH1, the second channel portion CH2, and the connection channel portion CH_{N}, and may be disposed in a spacing between the first channel portions CH1 secured by the exposed lower surfaces of the two connection channel portions CH_{N} in the two neighboring channel structures CH. The lower insulating regions SS may penetrate through at least one of the lower gate electrodes 130L between the first channel portion CH1, preferably at least two lower gate electrodes 130L1 and 130L2. Accordingly, a width of an upper surface of the lower insulating regions SS may be smaller than a width of a lower surface, and a level of an upper surface of the lower insulating regions SS may be lower than a level of a lower surface of the connection channel portion CH_{N}, and a level of a lower surface of lower insulating regions SS may be equal to or lower than a level of a lower surface of first channel portion CH1. The lower insulating regions SS may divide the lower gate electrodes 130L1 and 130L2 in the Y-direction, as illustrated in FIGS. 2A and 2B.

Each of the lower insulating regions SS may include a lower isolation insulating layer 103. The lower isolation insulating layer 103 may include an insulating material, for example, silicon oxide, silicon nitride, or silicon oxynitride.

The contact plugs 170 may be connected to the contact regions 130P of the gate electrodes 130 in the gate pad regions GP of the second region R2. The contact plugs 170 may penetrate through at least a portion of the cell region insulating layers 190 and may be connected to each of the contact regions 130P of the gate electrodes 130 exposed upwardly. The contact plugs 170 may penetrate through the gate electrodes 130 below contact regions 130P and may be connected to the circuit interconnection lines 280 in the first structure S1. The contact plugs 170 may be spaced apart from the gate electrodes 130 below the contact regions 130P by the contact insulating layers 160. In some example embodiments, the contact plugs 170 may be disposed to not penetrate through the gate electrodes 130, and in this case, the contact plugs 170 may be connected to the contact regions 130P of the gate electrodes 130 exposed upwardly, respectively.

The contact plugs 170 may have a shape corresponding to the channel structures CH or a shape corresponding to the isolation region MS. Each of the contact plugs 170 may include an upper region penetrating through the first to third gate structures GS1-GS3, respectively, and a lower region extending with the upper region and disposed below the upper region. The upper region may have a bent portion of which a width may be discontinuously changed below the horizontal insulating layer 101, as illustrated in FIG. 2A. The lower region may penetrate through the horizontal connection portion 121 and the lower gate structure GSL, and may have a bent portion of which a width may change discontinuously on an interfacial surface between the horizontal connection portion 121 and the lower gate structure GSL. The lower region and the upper region may have a sloped side surface of which a width may decrease downwardly from each gate structure GS due to an aspect ratio, and may have a cylindrical shape. A slope direction of the upper region and the lower region in each gate structure GS may be opposite to a slope direction of the lower insulating region SS. Each of the contact plugs 170 may include a landing region having a width extending in a lower portion, but example embodiments are not limited thereto.

As illustrated in FIG. 2A, each of the contact plugs 170 may have a horizontally extend shape in the contact region 130P. The contact plug 170 may include a vertical extension portion 170V extending in the Z-direction and a horizontal extension portion 170H extending horizontally from the vertical extension portion 170V and in contact with the gate electrode 130. The horizontal extension portion 170H may be disposed along a circumference of the vertical extension portion 170V, and the entire side surface may be surrounded by the gate electrode 130. A length from a side surface of the vertical extension portion 170V to an end of the horizontal extension portion 170H may be smaller than a length from a side surface of the vertical extension portion 170V to external side surfaces of the contact insulating layers 160. The contact plugs 170 may be spaced apart from the gate electrodes 130 below the contact regions 130P, for example, the gate electrodes 130 not electrically connected to each other, by the contact insulating layers 160.

The contact plugs 170 may include at least one of a conductive material, for example, at least one of tungsten (W), copper (Cu), aluminum (Al), and alloys thereof. In some example embodiments, the contact plugs 170 may include a barrier layer extending along a side surface and a bottom surface, or may have an air gap therein.

The contact insulating layers 160 may be disposed to surround side surfaces of each of the contact plugs 170 below the contact regions 130P. The contact insulating layers 160 may be spaced apart from each other in the Z-direction around each of the contact plugs 170. The contact insulating layers 160 may be disposed on substantially the same level as a level of the gate electrodes 130, respectively. The contact insulating layers 160 may include an insulating material, for example, at least one of silicon oxide, silicon nitride, or silicon oxynitride.

Lower contact plugs 173 may be connected to the lower gate electrodes 130L1 and 130L2. The lower contact plugs 173, differently from contact plugs 170, may not penetrating through the lower gate electrodes 130L1 and 130L2. The lower contact plugs 173 may be disposed to be partially recessed into the lower gate electrodes 130L1 and 130L2 from a lower surface, or to be connected to a lower surface. The lower contact plugs 173 may be connected to the lower gate electrodes 130L1 and 130L2, respectively, which may be isolated by the lower insulating region SS, and a portion of the first lower gate electrode 130L1 may be open for connection between the second lower gate electrode 130L2 and the lower contact plug 173. Accordingly, each lower contact plug may be disposed to be partially recessed from a lower surface of the corresponding lower gate electrode while being insulated from the upper and lower gate electrodes, or to be connected to the lower surface. The lower contact plug 173 may include a conductive material and may include the same material(s) as that of the contact plugs 170, but example embodiments are not limited thereto.

Support structures 165 may be disposed around the contact plugs 170. As illustrated in FIGS. 1A and 1B, the support structures 165 may be disposed in the second region R2 in a circular shape in a plan diagram, and may be arranged in a regular shape around the contact plugs 170. For example, four support structures 165 may be arranged around each contact plug 170, but example embodiments are not limited thereto. The support structures 165 may be disposed regularly and continuously even in regions in which the contact plugs 170 are spaced apart from each other in the X-direction. The support structures 165 are not limited to a circular shape on a plan diagram, and may have various shapes such as a polygon and an ellipse. As illustrated in FIG. 2A, a width of the support structures 165 may be equal to or smaller than a width of the contact plugs 170.

The support structures 165 may penetrate through the gate structures GS to have the same shape as that of the contact plugs 170 as illustrated in FIG. 2A, and may have a cylindrical shape having a width decreasing downwardly and having a sloped side surface in each gate structure GS. A slope direction of the support structures 165 may also be opposite to a slope direction of the lower insulating region SS. The support structures 165 may be formed of an insulating material.

The second structure S2 may further include through-vias 175 penetrating through the substrate insulating layer 192 in an edge region of the second region R2 and connected to the second interconnection structure 180 below. The through-vias 175 may penetrate the cell region insulating layer 190 and may have a cylindrical shape of which a width may decrease downwardly to have the same bent portion as that of the contact plugs 170. The through-vias 175 may include a conductive material and may include the same material(s) as that of the contact plugs 170, but example embodiments are not limited thereto.

The cell region insulating layer 190 may be disposed to cover the substrate insulating layer 192 and each gate pad region GP. The cell region insulating layer 190 may be formed of an insulating material and may include a plurality of insulating layers.

The passivation layer 106 may be disposed on upper surfaces of the horizontal conductive layer 102 and the horizontal insulating layer 101. The passivation layer 106 may function as a layer protecting the semiconductor device 100. In some example embodiments, the passivation layer 106 may have an opening in partial regions, and accordingly, a pad 108 connected to an external device may be formed. The passivation layer 106 may include at least one of silicon oxide, silicon nitride, and silicon carbide.

The studs 181 may form a cell interconnection structure 180 electrically connected to memory cells in the memory cell region CELL. The studs 181 may be electrically connected to the first channel portions CH1 and the contact plugs 170. The studs 181 may not be disposed on the support structures 165. The studs 181 may have a plug shape, but example embodiments are not limited thereto, and the studs 181 may also have a line shape. A portion of the studs 181 may include upper studs 183 connected to upper channel pad 149_U on an upper end of the channel structures CH, and may be electrically connected to the horizontal conductive layer 102. In some example embodiments, the number of the plugs 181 and the interconnection lines 184 included in the cell interconnection structure 180 may be varied. The studs 181 may include metal, for example, one or more of tungsten (W), copper (Cu), aluminum (Al), or the like.

Cell interconnection lines 184 may include bit lines of the first region R1 connected to the channel structures CH and interconnection lines of the second region R2 disposed on the same level as a level of the bit lines. The cell interconnection lines 184 may have a line shape extending in at least one direction and may be connected to the studs 181 through the plugs 182. The cell interconnection lines 184 may include, for example, one or more of tungsten (W), aluminum (Al), copper (Cu), tungsten nitride (WN), tantalum nitride (TaN), titanium nitride (TiN), or combinations thereof.

The second bonding vias 195 of the second bonding structure may be disposed below the second cell interconnection lines 184 and may be connected to the second cell interconnection lines 184, and the second bonding metal layers 198 of the second bonding structure may be connected to the second bonding vias 195. A lower surface of the second bonding metal layers 198 may be exposed to a lower surface of the second structure S2. The second bonding metal layers 198 may be bonded and connected to the first bonding metal layers 298 of the first structure S1. The second bonding vias 195 and the second bonding metal layers 198 may include a conductive material, for example, copper (Cu).

In some example embodiments, the lower horizontal insulating layer 193 may include a bonding insulating layer 199 having a predetermined thickness from a lower surface. In this case, the bonding insulating layer 199 may form dielectric-dielectric bonding with the bonding insulating layer 299 of the first structure S1. For example, the bonding insulating layer 199 may include at least one of SiO, SiN, SiCN, SiOC, SiON, and SiOCN.

The first and second structures S1 and S2 may be bonded to each other by bonding between the first bonding metal layers 298 and the second bonding metal layers 198 and bonding between the bonding insulating layers 199 and 299. The bonding between the first bonding metal layers 298 and the second bonding metal layers 198 may be or may include, for example, copper (Cu)-copper (Cu) bonding, and the bonding between the bonding insulating layers 199 and 299 may be or may include, for example, dielectric-dielectric bonding such as SiCN—SiCN bonding. The first and second structures S1 and S2 may be bonded to each other by hybrid bonding including copper (Cu)-copper (Cu) bonding and dielectric-dielectric bonding.

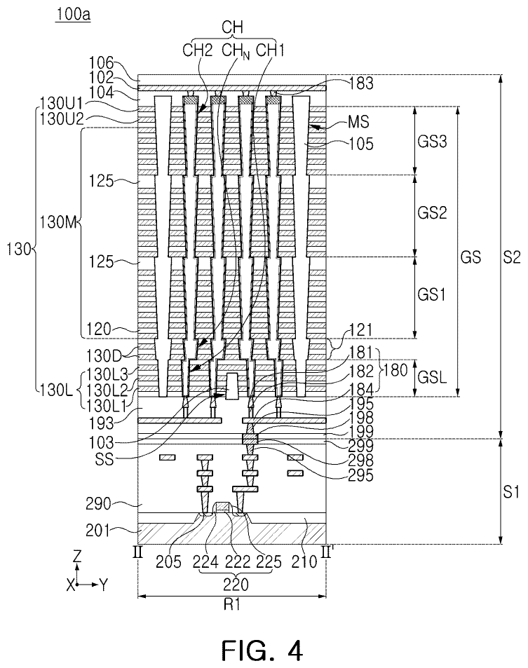

FIGS. 4 to 6 are cross-sectional diagrams illustrating a semiconductor device according to various example embodiments, illustrating a plane corresponding to FIG. 2B.

Referring to FIG. 4, in a semiconductor device 100a, the horizontal connection portion 121 through which the connection channel portion CH_{N} penetrates may further include connection gate electrodes 130D. The semiconductor device 100a may further include at least one connection gate electrode 130D stacked and spaced apart from each other in the Z-direction between the lower gate structure GSL and the first gate structure GS1 without forming a connection interlayer insulating layer. In the connection gate electrodes 130D, the gate electrode 130D and the interlayer insulating layer 120 may be alternately stacked, and a smaller number of the gate electrodes 130D than the number of the gate electrodes 130L1-130L3 of the lower gate structure GSL may be stacked. When the connection channel portion CH_{N} penetrates at least one connection gate electrode 130D, the connection gate electrode 130D may function as a dummy transistor. Accordingly, the lower insulating structure SS may penetrate through at least a portion of the lower gate electrodes 130L1-130L3, and the connection gate electrodes 130D may not penetrate therethrough. The connection gate electrodes 130D may function as a dummy gate electrode, such that the number of dummy gate electrodes in the lower gate structure GSL may be reduced. Accordingly, the size of the memory cell of the gate structure GS may be reduced while maintaining capacity thereof, and/or the height of the lower first channel portion CH1 may be reduced, which may improve fabrication thereof.

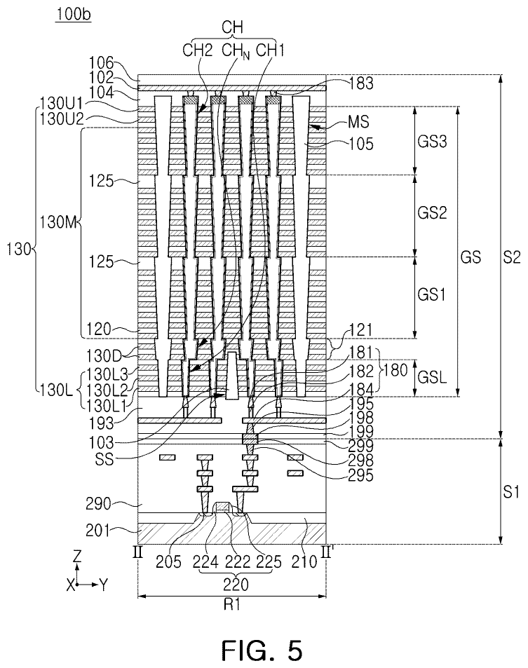

Referring to FIG. 5, as in various example embodiments in FIG. 4, in the semiconductor device 100b, the horizontal connection portion 121 through which the connection channel portion CH_{N} penetrates may further include connection gate electrodes 130D. When the connection channel portion CH_{N} penetrates through at least one connection gate electrode 130D, the connection gate electrode 130D may function as a dummy transistor. The lower insulating structure SS may penetrate through at least a portion of the lower gate electrodes 130L1-130L3, and may not penetrate through the connection gate electrodes 130D. The connection gate electrodes 130D may be or may function as dummy gate electrodes, e.g., gate electrodes that are not electrically active.

However, differently from FIG. 4, in the lower insulating region SS of the semiconductor device 100b, an upper surface of the lower insulating region SS may be disposed on a level higher than a level of a lower surface of the connection channel portion CH_{N} such that the lower insulating region SS may penetrate through the entirety of the lower gate electrodes 130L and at least one gate electrode 130D among the connection gate electrodes 130D. Accordingly, among the connection gate electrodes 130D in the horizontal connection portion 121, the gate electrode 130D not penetrated by the lower insulating region SS may function as a dummy gate electrode, and the gate electrode 130L in the lower gate structure GSL may function as a selection gate electrode, such that dummy gate electrodes in the lower gate structure GSL may be removed. Accordingly, the size of the memory cell of the gate structure GS may be reduced while maintaining capacity thereof, and/or a height of the lower first channel portion CH1 may be dramatically reduced, which may improve the manufacturability thereof.

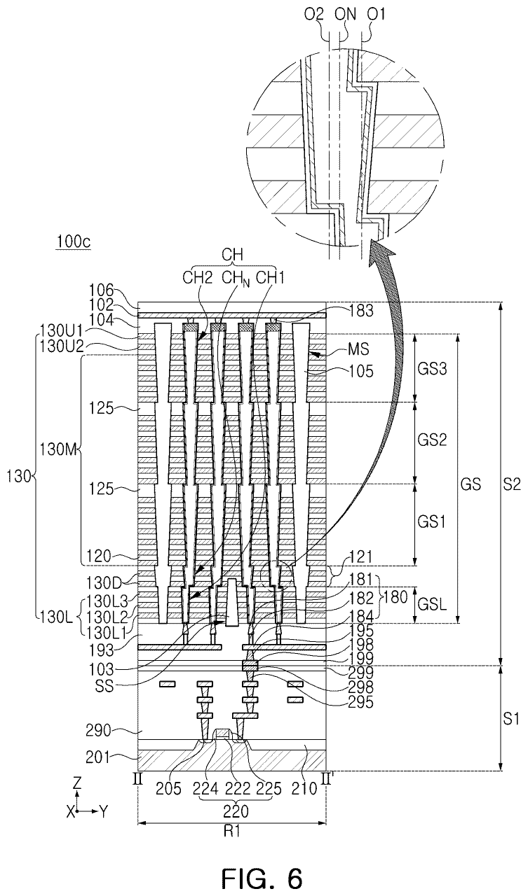

Referring to FIG. 6, in a semiconductor device 100c, a central line O1 of the first channel portion CH1 may be not disposed in a linear line in the Z-direction with a central line O_{N} of the connection channel portion CH_{N}, and may be shifted in the horizontal direction (Y-direction). Also, a central line O_{N} of the connection channel portion CH_{N} and a central line O2 of the second channel portion CH2 may not be disposed on a linear line in the Z-direction and may be shifted in the horizontal direction (Y-direction). In this case, offset directions of the first channel portion CH1, the connection channel portion CH_{N} and the second channel portion CH2 may be the same, and the channel structure CH may be gradually offset in the horizontal direction (Y-direction) downwardly in the Z-direction. As illustrated in FIG. 6, the offset directions may be opposite to each other between the two channel structures CH in which the lower insulating region SS is formed, and accordingly, a greater spacing between the connection channel portion CH_{N} may be assured or may be more likely to be assured.

When the lower insulating region SS is formed to have a large height so as to extend to a region between the connection channel portions CH_{N}, that is, when a level of an upper surface of the lower insulating region SS is higher than a level of the lower surface of the connection channel portion CH_{N}, a width of an upper surface of the lower insulating region SS may be secured to be a predetermined value or more, such that the lower insulating region SS may be formed without damaging the channel structure CH, thereby improving reliability.

Accordingly, when the connection channel portion CH_{N} penetrates through a plurality of connection gate electrodes 130D, the lower insulating region SS penetrating through a portion gate electrode of the connection gate electrodes 130D may be formed by stably etching. Accordingly, among the connection gate electrodes 130D in the horizontal connection portion 121, non-penetrated gate electrode may function as a dummy gate electrode, and the entirety of the gate electrodes 130L in the lower gate structure GSL may function as selection gate electrodes, and accordingly, the dummy gate electrode may be removed from the lower gate structure GSL. Accordingly, the size of the memory cell of the gate structure GS may be reduced while maintaining capacity thereof, and/or a height of the lower first channel portion CH1 may be dramatically reduced, which may improve the manufacturability thereof.

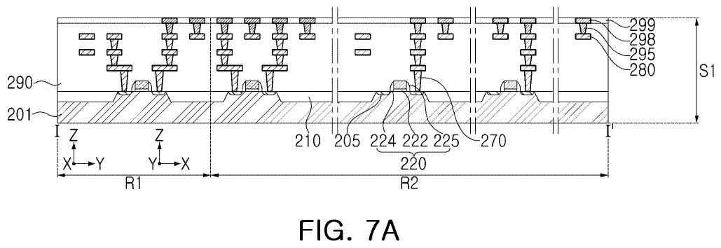

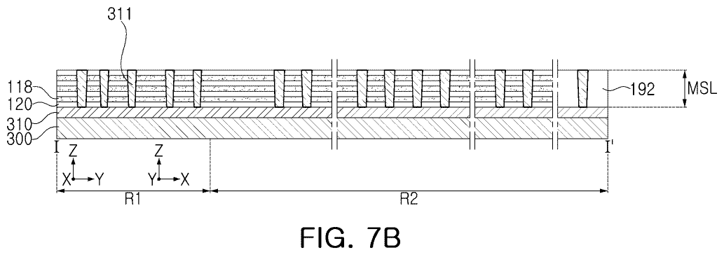

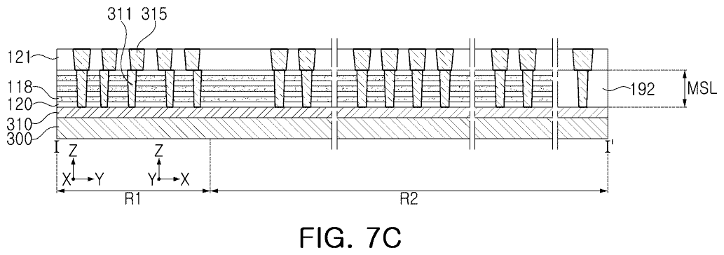

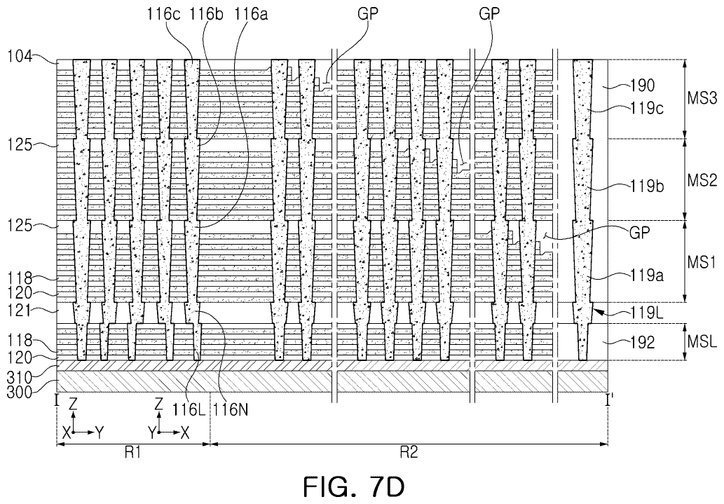

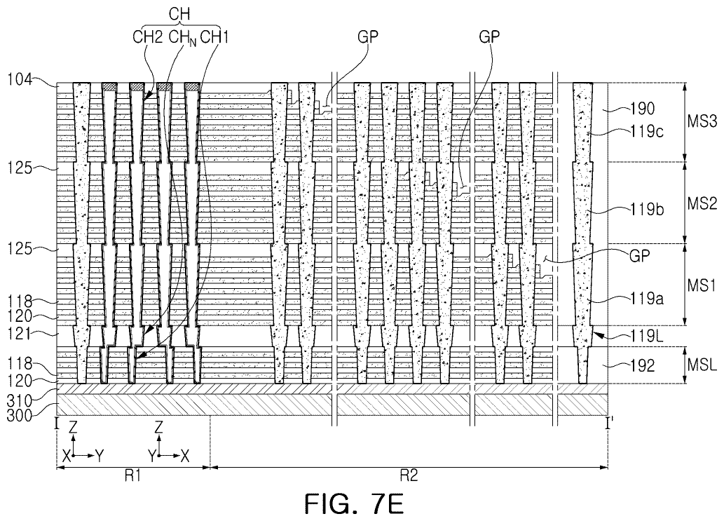

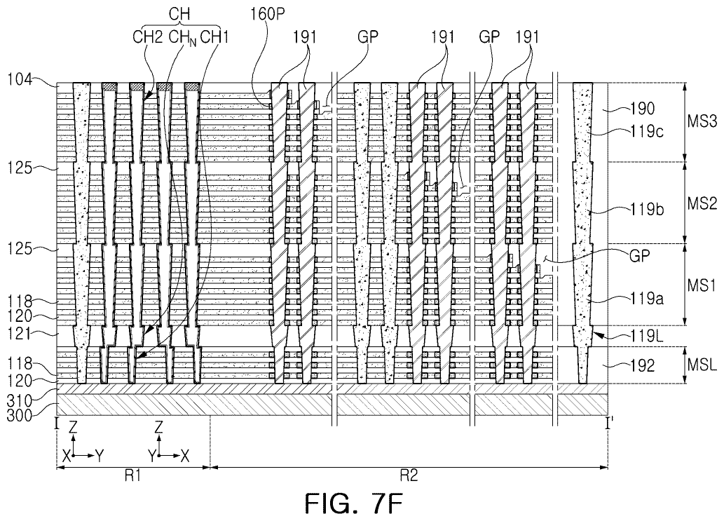

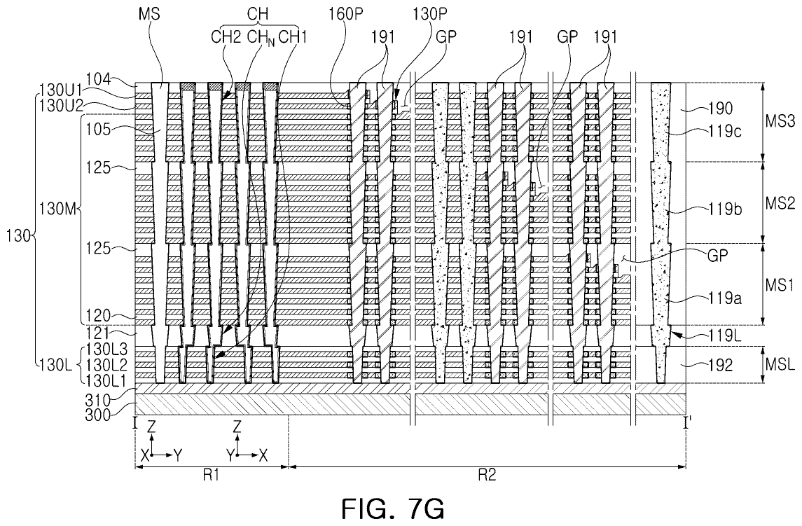

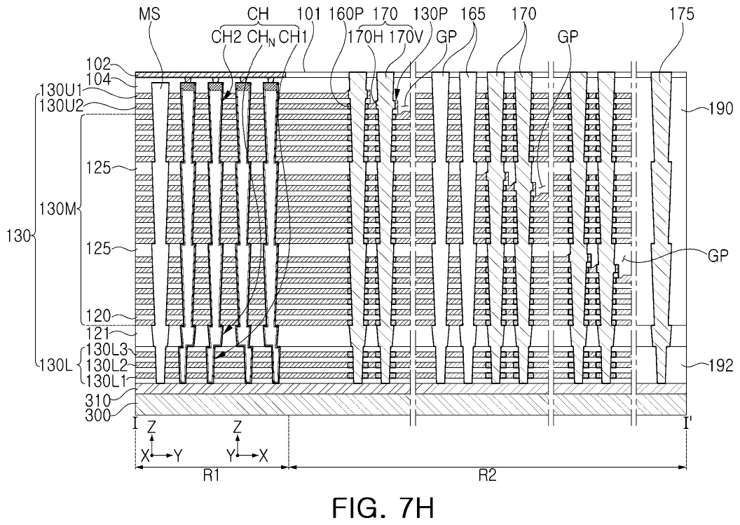

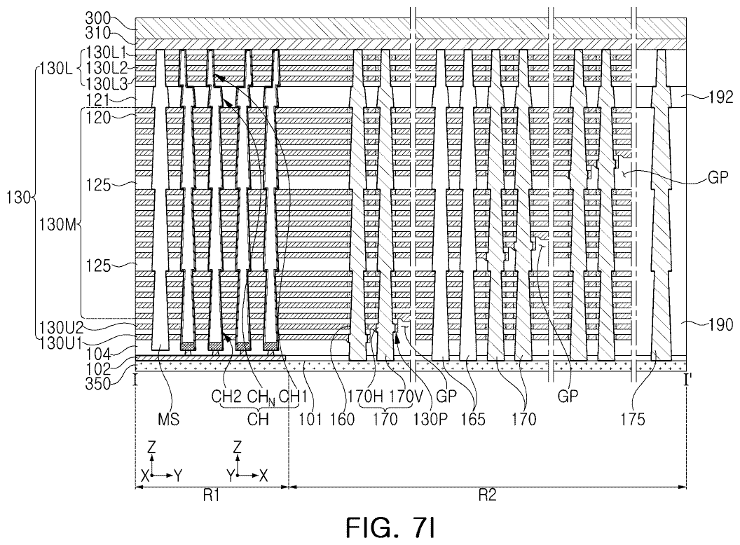

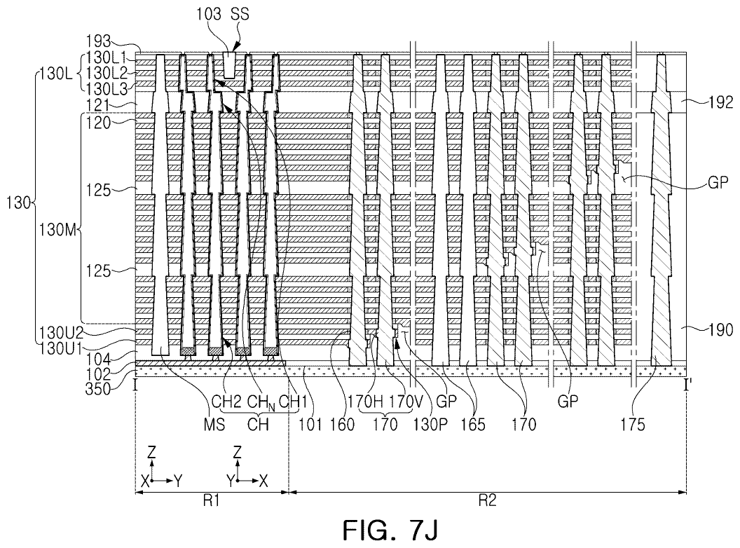

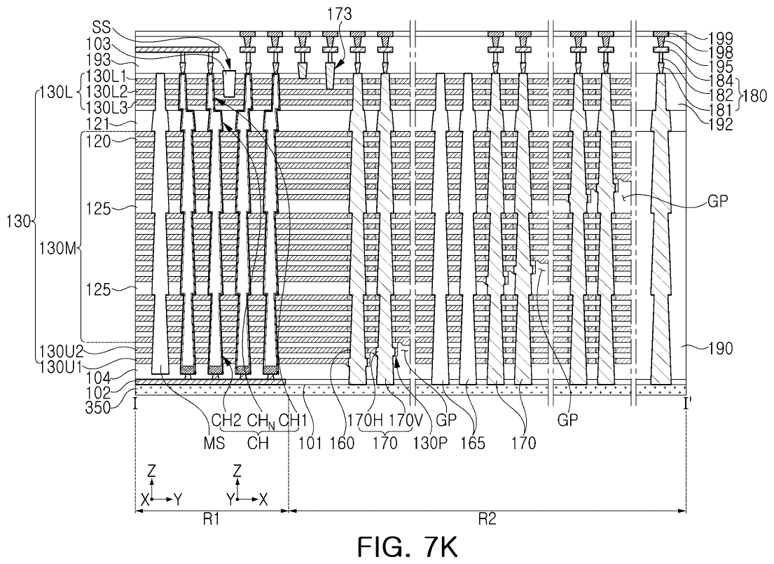

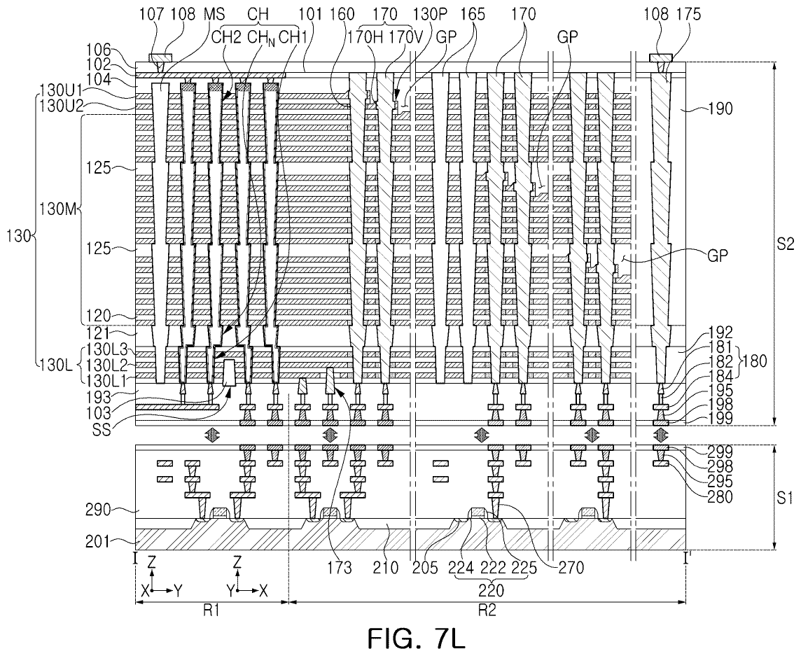

FIGS. 7A to 7I are cross-sectional diagrams illustrating a method of manufacturing a semiconductor device according to various example embodiments, illustrating cross-sectional surfaces corresponding to FIG. 2A.

Referring to FIG. 7A, a peripheral circuit region PERI including circuit devices 220 and circuit interconnection structures may be formed on a first substrate 201.

First, device isolation layers 210 may be formed in the first substrate 201, and a circuit gate dielectric layer 222 and a circuit gate electrode 225 may be formed in order on the first substrate 201. The device isolation layers 210 may be formed, for example, by a shallow trench isolation (STI) process. The circuit gate dielectric layer 222 and the circuit gate electrode 225 may be formed using atomic layer deposition (ALD) and/or chemical vapor deposition (CVD) and/or an oxidation process such as a thermal oxidation process. The circuit gate dielectric layer 222 may be formed of silicon oxide, and the circuit gate electrode 225 may be formed of at least one of polycrystalline silicon such as doped polysilicon or a metal silicide layer, but example embodiments are not limited thereto. Thereafter, a spacer layer 224 and source/drain regions 205 may be formed on both sidewalls of the circuit gate dielectric layer 222 and the circuit gate electrode 225. In some example embodiments, spacer layer 224 may include a plurality of layers. Thereafter, the source/drain regions 205 may be formed, for example, by performing an ion implantation process such as but not limited to a beamline implantation process and/or a plasma assisted ion doping process.

Among the circuit interconnection structures, circuit contact plugs 270 may be formed by partially forming the peripheral region insulating layer 290, removing a portion by etching, and filling a conductive material. Circuit interconnection lines 280 may be formed, for example, by depositing a conductive material and patterning the material.

The peripheral region insulating layer 290 may include a plurality of insulating layers. The peripheral region insulating layer 290 may be partially formed in each process of forming the circuit interconnection structures and by forming a portion of the uppermost circuit interconnection line 280, the peripheral region insulating layer 290 may finally be formed to cover the circuit devices 220 and the circuit interconnection structures.

Thereafter, referring to FIG. 7B, a lower mold structure MSL and a substrate insulating layer 192 in which a memory cell region is provided may be formed on the sacrificial substrate 300, and first etching stop patterns 311 may be formed.

The sacrificial substrate 300 may be removed while the second structure S2 is formed, and may be, for example, a silicon substrate. A sacrificial substrate insulating layer 310 may be further formed on the sacrificial substrate 300, but example embodiments are not limited thereto. The sacrificial substrate insulating layer 310 may be or may include a portion oxide layer of the sacrificial substrate 300, but example embodiments are not limited thereto.

A lower mold structure MSL may be formed on the sacrificial substrate insulating layer 310, and first etching stop patterns 311 penetrating through the lower mold structure MSL may be formed.

The lower mold structure MSL may be formed on the sacrificial substrate insulating layer 310 on a level on which the lower gate structure GSL (see FIG. 2B) is disposed.

At least a portion of the sacrificial insulating layers 118 may be replaced with a portion of the gate electrodes 130 (see FIG. 2A) through a subsequent process. The sacrificial insulating layers 118 may be formed of a material different from that of the interlayer insulating layers 120, and may be formed of a material etched with etch selectivity under specific etching conditions for the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120, selected from among silicon, silicon oxide, silicon carbide, and silicon nitride. The number of and/or the thickness of interlayer insulating layers 120 and the sacrificial insulating layers 118 may be varied from the illustrated example, and as an example, the sacrificial insulating layers 118 may have three to seven layers. A substrate insulating layer 192 in which the through-via 175 is disposed may be formed on an edge region of the second region R2. The substrate insulating layer 192 may be planarized to be coplanar with an upper surface of the lower mold structure MSL.

A plurality of first etching stop patterns 311 penetrating through the lower mold structure MSL and the substrate insulating layer 192 may be formed.

The plurality of first etching stop patterns 311 may be formed in a region in which vertical structures of the isolation regions MS, the channel structures CH, the support structures 165, the contact plugs 170 and the through-vias 175 are disposed. First, the lower mold structure MSL and the substrate insulating layer 192 may be formed, and an opening may be formed by removing a portion of the lower mold structure MSL and the substrate insulating layer 192 to open the sacrificial substrate insulating layer 310 in the region in which each of the vertical structure is disposed. By filling each opening with an etching stop material and planarizing the material, the first etching stop patterns 311 may be formed.

The first etching stop patterns 311 may be formed to correspond to the lower region of each vertical structure, and a side surface may have a slope such that a width of the upper surface may be the largest and a width of the lower surface may be the smallest. The first etching stop patterns 311 may be formed such that a width may decrease in the Z-direction toward the sacrificial substrate 300 or the first structure S1 to be bonded later. The first etching stop patterns 311 may be formed of a metal material such as tungsten (W), and may function as a pattern to stop etching in anisotropic etching.

Referring to FIG. 7C, as a horizontal connection portion 121, a lower interlayer insulating layer 121 may be formed on the lower mold structure MSL, and the second etching stop patterns 315 may be formed.

The lower interlayer insulating layer 121 may be formed on the lower mold structure MSL and the substrate insulating layer 192, may be formed of the same material as that of the interlayer insulating layer 120, and may be formed of at least one of silicon oxide and silicon nitride. The lower interlayer insulating layer 121 may be 5 to 10 times, preferably 7 to 10 times, a thickness of the sacrificial insulating layer 118, but example embodiments are not limited thereto. A thickness of the lower interlayer insulating layer 121 may be smaller than a thickness of the lower mold structure MSL.

A plurality of second etching stop patterns 315 penetrating through the lower interlayer insulating layer 121 may be formed. The plurality of second etching stop patterns 315 may be formed on the first etching stop patterns 311 formed in a lower portion, and may be formed in a region in which the vertical structures of the isolation regions MS, the channel structures CH, the support structures 165, the contact plugs 170 and the through-vias 175 are disposed. First, the lower interlayer insulating layer 121 may be formed, and an opening may be formed by removing a portion of the lower interlayer insulating layer 121 to open the first etching stop patterns 311 in the region in which each vertical structure is disposed. By filling each opening with an etching stop material and planarizing the material, the second etching stop patterns 315 may be formed.

The second etching stop patterns 315 may be formed to correspond to the lower region of each vertical structure, and a side surface may have a slope such that a width of an upper surface may be the largest and a width of a lower surface may be the smallest. The second etching stop patterns 315 may be formed such that a width thereof may decrease in the Z-direction toward the sacrificial substrate 300 or the first structure S1 to be bonded later.

An upper surface of the second etching stop patterns 315 may have a width larger than that of an upper surface of the first etching stop patterns 311. Specifically, the second etching stop patterns 315 formed in the region in which the isolation regions MS, the support structures 165, the contact plugs 170 and the through-vias 175 are disposed may be formed to align with the first etching stop patterns 311 disposed therebelow. The alignment may indicate that a central line of a width of the second etching stop patterns 315 and a central line of a width of the first etching stop patterns 311 may form the same axis.

In this case, the second etching stop patterns 315 in the region in which the channel structure CH is disposed may be offset from the first etching stop patterns 311. The offsetting may indicate that a central line of a width of the second etching stop patterns 315 and a central line of a width of the first etching stop patterns 311 may be deviated in the horizontal direction, such that the lines may not form the same axis. The offset directions of the second etching stop patterns 315 and the first etching stop patterns 311 of the region in which the channel structures CH on both sides are disposed may be opposite to each other with respect to the region in which the lower insulating region SS is disposed. Accordingly, as illustrated in FIG. 7C, a spacing may be formed between the first etching stop patterns 311 such that a portion of a lower surface of the second etching stop patterns 315 in the region in which the channel structure CH is disposed may be exposed to an upper portion of the lower mold structure MSL.

The second etching stop patterns 315 may be formed of the same material as that of the first etching stop patterns 311, may be formed of a metal material such as tungsten (W), and may be or may function as a pattern to stop etching in anisotropic etching.

As illustrated in FIG. 7D, mold structures MS1-MS3 may be further formed, and a plurality of sacrificial vertical structures 116 and 119 may be formed. The first mold structure MS1 of the mold structure MS may be formed on the lower interlayer insulating layer 121, the first etching stop patterns 311 and the second etching stop patterns 315 may be replaced with the lower sacrificial layer layers 116L, 116N, and 119L, and the first channel sacrificial layers 116a and the first vertical sacrificial layers 119a penetrating through the first mold structure MS1 may be formed on the lower sacrificial layer layers 116L, 116N, and 119L.

The first mold structure MS1 may be formed on the lower interlayer insulating layer 121 on a level on which the first gate structure GS1 (see FIG. 2A) is disposed.

At least a portion of the sacrificial insulating layers 118 may be replaced with a portion of the gate electrodes 130 (see FIG. 2A) through a subsequent process. The sacrificial insulating layers 118 may be formed of a material different from that of the interlayer insulating layers 120, and may be formed of a material etched with etch selectivity under specific etching conditions for the interlayer insulating layers 120. For example, the interlayer insulating layer 120 may be formed of at least one of silicon oxide and silicon nitride, and the sacrificial insulating layers 118 may be formed of a material different from that of the interlayer insulating layer 120, selected from among silicon, silicon oxide, silicon carbide, and silicon nitride. The number of the interlayer insulating layers 120 and the sacrificial insulating layers 118 may be varied from the illustrated example.

The gate pad region GP may be formed by repeatedly performing a photolithography process and an etching process for the sacrificial insulating layers 118 and the interlayer insulating layers 120. The gate pad regions GP may be formed in the second region R2, and may include a region in which the upper sacrificial insulating layers 118 may extend shorter than the lower sacrificial insulating layers 118. In the gate pad region GP, asymmetrical step structures may be formed such that upper surfaces and ends of the plurality of sacrificial insulating layers 118 may be exposed upwardly. However, in some example embodiments, the specific shape of the gate pad region GP may be varied. By further forming the sacrificial insulating layers 118 on the step structure of the gate pad regions GP, the sacrificial insulating layers 118 disposed in the uppermost portion of each region may have a relatively great thickness.

Thereafter, a cell region insulating layer 190 covering the first mold structure MS1 may be formed. The first channel sacrificial layers 116a may be formed in a position corresponding to the channel structures CH (see FIG. 2A) in the first region R1. The first vertical sacrificial layers 119a may be formed in a position corresponding to the contact plugs 170 and the through-via 175 in the second region R2 and in a position corresponding to the insulating region MS in the first region. The first channel sacrificial layers 116a and the first vertical sacrificial layers 119a may be formed simultaneously.

The first channel sacrificial layers 116a, the first vertical sacrificial layers 119a and the lower sacrificial layer layers 116L, 116N, and 119L may be formed by forming first holes to penetrate through the first mold structure MS1, removing the first etching stop patterns 311 and the second etching stop patterns 315 through the first holes, depositing a sacrificial material, and performing a planarization process such as an etch-back process and/or a chemical mechanical planarization (CMP) process.

Specifically, the first holes for the first channel sacrificial layers 116a and the first vertical sacrificial layers 119a may be formed on each of second etching stop patterns 315. The second etching stop patterns 315 may function as an etching stop layer in etching to form the first hole, and the etching of the first hole may be formed to be partially recessed into an upper surface or from an upper surface of the second etching stop patterns 315. A material layer forming the first etching stop patterns 311 and the second etching stop patterns 315 exposed in a lower portion may be removed through the first hole, and a sacrificial material may be filled in both the opening region and the first hole in which the first etching stop patterns 311 and second etching stop patterns 315 were disposed.

Accordingly, in the region in which the channel structure CH is disposed, lower channel sacrificial layers 116L may be formed in the region in which the first etching stop pattern 311 was disposed, connection channel sacrificial layers 116N may be formed in the region in which the second etching stop pattern 315 was disposed, and first channel sacrificial layers 116a may be formed in the first mold structure MS1. The multilayer structure may be equally formed in the other vertical structures, the contact plugs 170, the through-via 175, the support structures 165, and the first vertical sacrificial layers 119a formed in the region in which the insulating region MS is disposed. The lower sacrificial layer layers 116L, 116N, and 119L, the first channel sacrificial layer 116a and the first vertical sacrificial layers 119a may include, for example, at least one of TiN and polycrystalline silicon.

The second mold structure MS2, the second channel sacrificial layers 116b, and the second vertical sacrificial layers 119b may be formed on the first mold structure MS1 in the same manner as the first mold structure MS1, the first channel sacrificial layers 116a, and the first vertical sacrificial layers 119a, respectively. The gate pad region GP may be formed on the second mold structure MS2, and a cell region insulating layer 190 covering the second mold structure MS2 may be formed. The second channel sacrificial layers 116b may be connected to the first channel sacrificial layers 116a, respectively, and the second vertical sacrificial layers 119b may be connected to the first vertical sacrificial layers 119a, respectively. The second channel sacrificial layers 116b and the second vertical sacrificial layers 119b may be formed simultaneously. The second channel sacrificial layers 116b and the second vertical sacrificial layers 119b may be formed by depositing the same material as that of the first channel sacrificial layers 116a and the first vertical sacrificial layers 119a.

A third mold structure MS3 may be formed by alternatively stacking sacrificial insulating layers 118 and interlayer insulating layers 120 on the second mold structure MS2, and a gate pad region GP may be formed, and third channel sacrificial layers 116c and third vertical sacrificial layers 119c may be formed.

The third mold structure MS3 may be formed on the second mold structure MS2 in the same manner as the first and second mold structures MS1 and MS2. The gate pad region GP may be formed on the third mold structure MS3, and a cell region insulating layer 190 covering the third mold structure MS3 may be formed.

The third channel sacrificial layers 116c may be formed to be connected to the second channel sacrificial layers 116b, respectively, and the third vertical sacrificial layers 119c may be formed to be connected to the second vertical sacrificial layers 119b, respectively. The third channel sacrificial layers 116c and the third contact sacrificial layers 119c may be formed simultaneously. The third channel sacrificial layers 116c and the third contact sacrificial layers 119c may be formed by depositing the same material as that of the first and second channel sacrificial layers 116a and 116b and the first and second contact sacrificial layers 119a and 119b.

Referring to FIG. 7E, the channel structures CH penetrating through the mold structure MS may be formed.

The channel structures CH may be formed by forming channel holes by removing the first to third channel sacrificial layers 116a, 116b, and 116c, a connection channel sacrificial layer 116N and a lower channel sacrificial layer 116L, and depositing at least a portion of the gate dielectric layer 145, the channel layer 140, the channel filling insulating layer 147 and the upper channel pad 149_U in order in the channel holes.

The gate dielectric layer 145 may be formed to have a uniform thickness using an ALD or CVD process. In this process, the entirety or a portion of the gate dielectric layer 145 may be formed, and a portion extending perpendicular to the interlayer insulating layer 120 along the channel structures CH may be formed in this process. The channel layer 140 may be formed on the gate dielectric layer 145 in the channel holes. The channel filling insulating layer 147 may be formed to fill the channel holes and may be an insulating material. The upper channel pad 149_U may be formed of a conductive material, for example, polycrystalline silicon.

Accordingly, the channel structures CH each including a first channel portion CH1, a connection channel portion CH_{N}, and a second channel portion CH2 may be formed. In the channel structures CH formed as above, a width of a central line O2 of the second channel portion CH2 and a width of a central line O2 of the connection channel portion CH_{N} may coincide, and a central line O1 of a width of the first channel portion CH1 may be offset in the horizontal direction from a central line O1 of a second channel portion CH2. Also, each of the first channel portion CH1, the connection channel portion CH_{N} and the second channel portions CH2 may have a side surface having a slope of which a width may decrease toward the lower mold structure MSL, that is, downwardly in the Z-direction. The second channel portion CH2 may be connected to have a discontinuous step on a boundary surface of each mold structure MS, and accordingly, the sub-channel portions CHa, CHb, and CHc penetrating through the mold structures MS may have a bent portion to have an upper surface having a width greater than that of a lower surface, may have a width decreasing downwardly in the Z-direction, and may also have a bent portion between the first sub-channel portion CHa of the second channel portion CH2 and the connection channel portion CH_{N}.

Referring to FIG. 7F, contact holes may be formed by removing the first to third vertical sacrificial layers and the lower sacrificial layer layers 119a and 119b, 119c, and 119L corresponding to the contact plugs 170 among the first to third vertical sacrificial layers 119a and 119b, and 119c, and preliminary contact insulating layers 160P and vertical sacrificial layers 191 may be formed in each of the contact holes through a wet etching process.

First, a portion of the sacrificial insulating layers 118 exposed through the contact hole may be removed. Contact tunnel portions may be formed by removing the sacrificial insulating layers 118 to a predetermined length around the contact holes. The contact tunnel portions may be formed to have a relatively short length in the uppermost sacrificial insulating layers 118, and may be formed to have a relatively long length in the lower sacrificial insulating layers 118.

Specifically, firstly, the contact tunnel portions may have a relatively long length in the uppermost sacrificial insulating layers 118, which may be because the uppermost sacrificial insulating layers 118 may include a region having a relatively high etch rate than that of the sacrificial insulating layers 118 therebelow. Thereafter, sacrificial layers may be formed in the contact holes and the contact tunnel portions. The sacrificial layer may be formed of a material of which an etching rate may be lower than that of the sacrificial insulating layers 118. Thereafter, a portion of the sacrificial layer and the sacrificial insulating layers 118 may be removed. In this case, the sacrificial layer may remain in the uppermost portion, and a portion of the sacrificial insulating layers 118 may be removed from the lower portion after the sacrificial layer is removed. Accordingly, ultimately, the contact tunnel portions may be formed to have a relatively short length in the uppermost sacrificial insulating layers 118.

By depositing an insulating material in the first contact holes and the contact tunnel portions, preliminary contact insulating layers 160P may be formed. The preliminary contact insulating layers 160P may be formed on a sidewall of the first contact holes and may fill the contact tunnel portions. In the uppermost sacrificial insulating layers 118, the preliminary contact insulating layers 160P may not completely fill the contact tunnel portions.

The vertical sacrificial layers 191 may fill the contact holes and the uppermost contact tunnel portions. The contact holes may include materials different from that of the preliminary contact insulating layers 160P, for example, polycrystalline silicon.

Referring to FIG. 7G, a plurality of gate electrodes 130 may be formed. Openings penetrating through the sacrificial insulating layers 118 and the interlayer insulating layers 120 and extending to the sacrificial substrate insulating layer 310 may be formed in positions of the isolation regions MS (see FIGS. 1 and 2A and 2B). Thereafter, the sacrificial insulating layers 118 may be selectively removed with respect to the interlayer insulating layers 120 and the preliminary contact insulating layers 160P, for example, using wet etching, and accordingly, gate tunnel portions may be formed. The gate electrodes 130 may be formed by depositing a conductive material on the gate tunnel portions. The conductive material may include metal, polycrystalline silicon, or metal silicide material. In some example embodiments, a portion of the gate dielectric layer 145 may be formed preferentially before forming the gate electrodes 130. Accordingly, a gate structure GS including the first to third gate structures and the lower gate structures GS1, GS2, GS3, and GSL may be formed. After forming the gate electrodes 130, gate isolation insulating layers 105 may be formed in the openings formed to correspond to the isolation regions MS.

Thereafter, referring to FIG. 7H, a horizontal conductive layer 102 may be formed in the first region R1, and contact plugs 170 may be formed.

Specifically, an upper insulating layer 104 covering the vertical sacrificial layers 119a and 119b, 119c, and 119L formed in the region in which the isolation region MS, the channel structures CH, the contact plugs 170, and the support structures 165, and the through-vias 175 are disposed may be formed.

The upper insulating layer 104 may be formed of silicon oxide, but example embodiments are not limited thereto. Upper studs 183 connected to the upper channel pad 149_U of each channel structure CH may be formed in the upper insulating layer 104.

A horizontal conductive layer 102 covering the upper studs 183 may be formed in the first region R1.

For example, the horizontal conductive layer 102 may be formed of polycrystalline silicon and may be formed by a CVD process. Polycrystalline silicon forming the horizontal conductive layer 102 may include impurities. A horizontal insulating layer 101 may be formed on the upper insulating layer 104 of the second region R2. The horizontal insulating layer 101 and the horizontal conductive layer 102 may be formed on the same layer, only the horizontal conductive layer 102 may be formed as a conductive layer by selectively doping impurities.

The horizontal insulating layer 101 may be formed, and openings for opening the upper surface of each vertical structure may be formed.

The vertical sacrificial layers 191 in the vertical structure in which the contact plugs 170 are disposed may be removed through the openings, and the contact plugs 170 may be formed. Specifically, the vertical sacrificial layers 191 may be selectively removed with respect to the interlayer insulating layers 120 and the gate electrodes 130. A portion of the preliminary contact insulating layers 160P exposed after the vertical sacrificial layers 191 are removed may also be removed. In this case, the entirety of the preliminary contact insulating layers 160P may be removed from the contact regions 130P, and the preliminary contact insulating layers 160P may remain therebelow and may form the contact insulating layers 160. In the contact regions 130P, when the gate dielectric layer 145 is exposed after the preliminary contact insulating layers 160P are removed, a side surface of the gate electrodes 130 may be exposed by removing the gate dielectric layer 145, and contact plugs 170 may be formed by depositing a conductive material. The contact plugs 170 may be formed to have horizontal extension portions 170H (see FIG. 2B) extending horizontally from the contact regions 130P, and accordingly, the contact plugs may be physically and electrically connected to the gate electrodes 130. The sacrificial layers 119a and 119b, 119c, and 119L in the region in which through-via 175 is disposed may also be removed through the opening of the horizontal insulating layer 101, and a through-via 175 may be formed by depositing a conductive material. Also, the vertical sacrificial layers 119a and 119b, 119c, and 119L in the region in which the support structures 165 are disposed may also be removed through the opening of the horizontal insulating layer 101, and the support structures 165 may be formed by depositing an insulating material.

As described above, the contact plugs 170, the through-vias 175 and the support structures 165 may have upper surfaces on a level higher than a level of an upper surface of the channel structures CH, and may have an upper surface on the same level as a level of an upper surface of the horizontal conductive layer 102, but example embodiments are not limited thereto.

Thereafter, referring to FIG. 7I, by transferring the horizontal conductive layer 102 and the gate structure GS in which the horizontal insulating layer 102 is formed to carrier substrate 350, the lower sacrificial substrate 300 may be disposed upside down to be exposed upwardly.

Specifically, when the gate structure GS is disposed upside down such that the horizontal conductive layer 102 and the horizontal insulating layer 101 are in contact with the carrier substrate 350, the channel structures CH, the insulating regions MS, the contact plugs 170 and the through-vias 175 may be disposed in an opposite manner such that widths thereof may increase downwardly below the sacrificial substrate 300 and the sacrificial substrate insulating layer 310 exposed upwardly.

Thereafter, referring to FIG. 7J, a lower insulating region SS penetrating through the lower gate structure GSL exposed upwardly may be formed.

Specifically, the sacrificial substrate 300 exposed upwardly may be removed by etching.

When the sacrificial substrate 300 is removed, the sacrificial substrate insulating layer 310 may also be removed, such that a lower surface of the lower gate structure GSL may be exposed upwardly. A lower insulating region SS to isolate at least one lower gate electrode 130L1 from a lower surface of the exposed lower gate structure GSL may be formed.

As illustrated in FIGS. 2A and 2B, the lower insulating region SS may be formed in a spacing secured by offsetting the first channel portion CH1 in opposite directions, and the lower insulating region SS may be formed by forming an opening by etching to isolate at least one lower gate electrode 130L1 and 130L, and filling the opening with an insulating material.

The opening forming the lower insulating region SS may be etched from the lower surface exposed upwardly, such that a width of a lower surface may be the largest and a width may decrease upwardly, and the opening may have a slope in a direction opposite to a slope direction of the first channel portion CH1.

Accordingly, as a lower surface forming the largest width of the lower insulating region SS is disposed between lower surfaces having the smallest width of the first channel portion CH1, thereby ensuring a process margin and the lower insulating region SS may be formed without damaging the first channel portion CH1.

A depth of the lower insulating region SS may be determined to penetrating through lower gate electrodes 130L1 and 130L2 functioning as string selection transistors among the lower gate electrodes 130L1 and 130L2, and when a portion of dummy gate electrodes is present in the lower gate structure GSL, a portion of the lower gate electrodes 130L3 may not be isolated by the lower insulating region SS, as illustrated in FIG. 7J. Accordingly, a level of an upper surface of the lower insulating region SS may be lower than a level of an upper surface of the lower gate structure GSL.

In this case, a lower channel pad 149_L may be further formed by opening the gate dielectric layer 145 in a portion of a lower surface of the first channel portion CH1 of the channel structure CH, and doping impurities to the exposed channel layer 140.

The doping of impurities may be performed after forming the lower horizontal insulating layer 193 on the exposed lower gate structure GSL, forming an opening to open the end of the first channel portion CH1 of the channel structure CH, and opening the gate dielectric layer 145 through the opening. When the lower insulating region SS and the lower channel pad 149_L are formed after forming the lower horizontal insulating layer 193 as described above, a lower surface of the lower insulating region SS may have a level lower than a level of the lower surface of the lower gate structure GSL.

Thereafter, referring to FIG. 7K, cell interconnection structures 180 and second bonding structure may be formed on a lower surface of the lower gate structure GSL.

The studs 181 and the cell interconnection structures 180 connected to the studs 181 may be formed by etching the lower horizontal insulating layer 193 on the lower channel pads 149_L, the contact plugs 170 and the through-vias 175 and depositing and patterning a conductive material. The cell interconnection lines 184 may include bit lines. In this case, the lower contact plug 173 may also be deposited together with the studs 181, or may be deposited in another process.

The second bonding vias 195 and the second bonding metal layers 198 forming the second bonding structure may be formed by further forming the bonding insulating layer 199 on the cell interconnection structures 180 and partially removing the layer. An upper surface of the second bonding metal layers 198 may be exposed from the bonding insulating layer 199.

Referring to FIG. 7L, the first structure S1 and the second structure S2 may be bonded to each other.

The first structure S1 and the second structure S2 may be connected to each other by bonding the first bonding metals 298 to the second bonding metal layers 198 by pressing. Simultaneously, the bonding insulating layers, which are a portion of the peripheral region insulating layer 290 and the cell region insulating layer 190, may also be bonded to each other by pressing. Specifically, the second structure S2 may be disposed upside down on the first structure S1 such that the second bonding metal layers 198 may face downwardly, and bonding may be performed. In the drawing, the second structure S2 may be bonded in the form of a mirror image of the structure illustrated in FIG. 7K.

The first structure S1 and the second structure S2 may be directly bonded to each other without an adhesive such as an adhesive layer interposed therebetween. In some example embodiments, before bonding, a surface treatment process such as hydrogen plasma treatment may be further performed on an upper surface of the first structure S1 and a lower surface of the second structure S2 to strengthen the bonding force.

The carrier substrate 350 of the second structure S2 may be removed from the bonding structure of the first and second structures S1 and S2, and a passivation layer 106 may be further formed on the exposed upper surface, that is, the horizontal conductive layer 102 and the horizontal insulating layer 102.

A pad structure 108 connected to an external entity may be further formed on the passivation layer 106. The pad structure 108 may include a connection via 107 for connection between the lower structure of the passivation layer 106 and a pad structure 108 disposed above the passivation layer 106, and accordingly, the semiconductor device 100 may be manufactured.

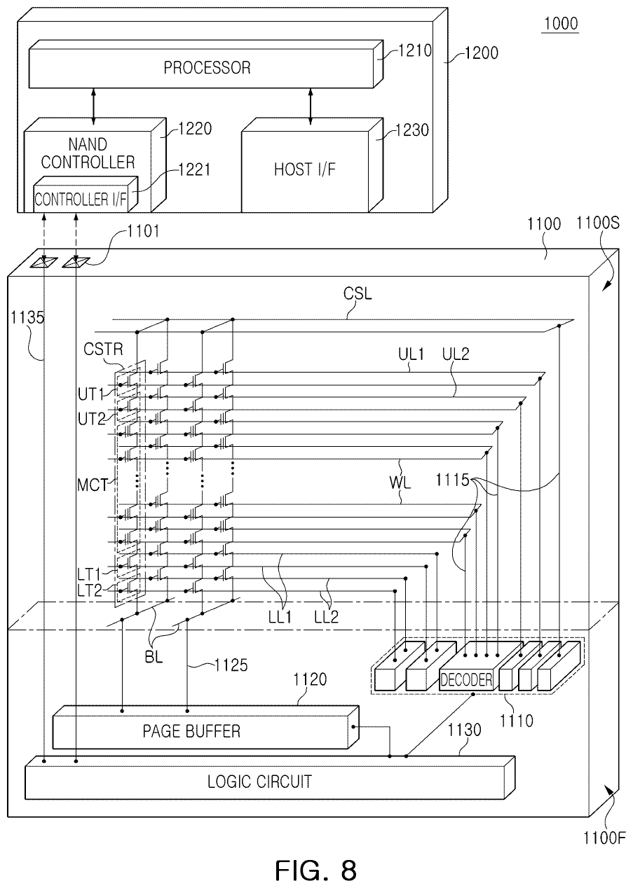

FIG. 8 is a diagram illustrating a data storage system including a semiconductor device according to some example embodiments.

Referring to FIG. 8, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 6. The semiconductor device 1100 may include a first structure 1100F and a second structure 1100S on the first structure 1100F. In various example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in various example embodiments.

In various example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In various example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In various example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

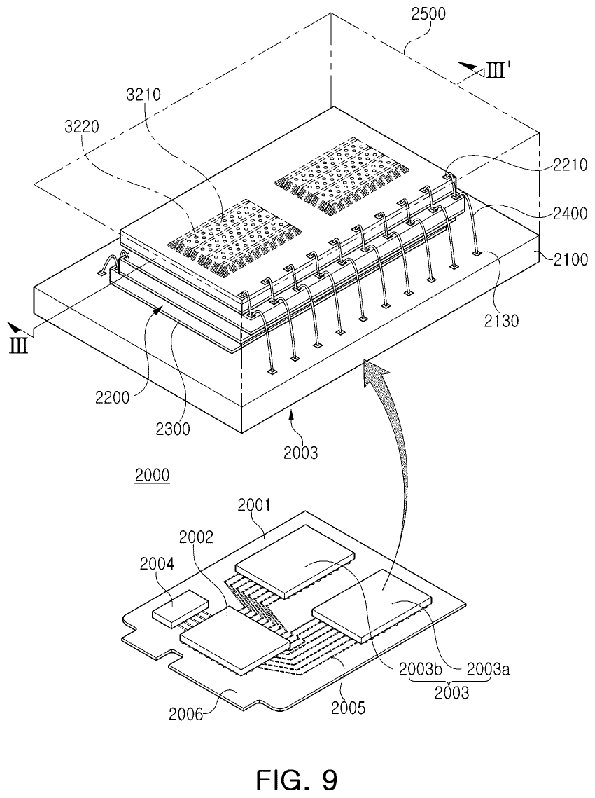

FIG. 9 is a perspective diagram illustrating a data storage system including a semiconductor device according to various example embodiments.

Referring to FIG. 9 a data storage system 2000 in some example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may be varied depending on a communication interface between the data storage system 2000 and the external host. In various example embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In various example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 8. Each of the semiconductor chips 2200 may include gate stack structures 3210 and channel structures 3220. Each of the semiconductor chips 2200 may include the semiconductor device described in the aforementioned example embodiment with reference to FIGS. 1 to 6.

In various example embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In various example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In various example embodiments, the controller 2002 and the semiconductor chips 2200 may be included in a single package. In some example embodiments, the controller 2002 and the semiconductor chips 2200 may be mounted on an interposer substrate different from the main board 2001, and the controller 2002 and the semiconductor chips 2200 may be connected to each other by interconnection formed on the interposer substrate.

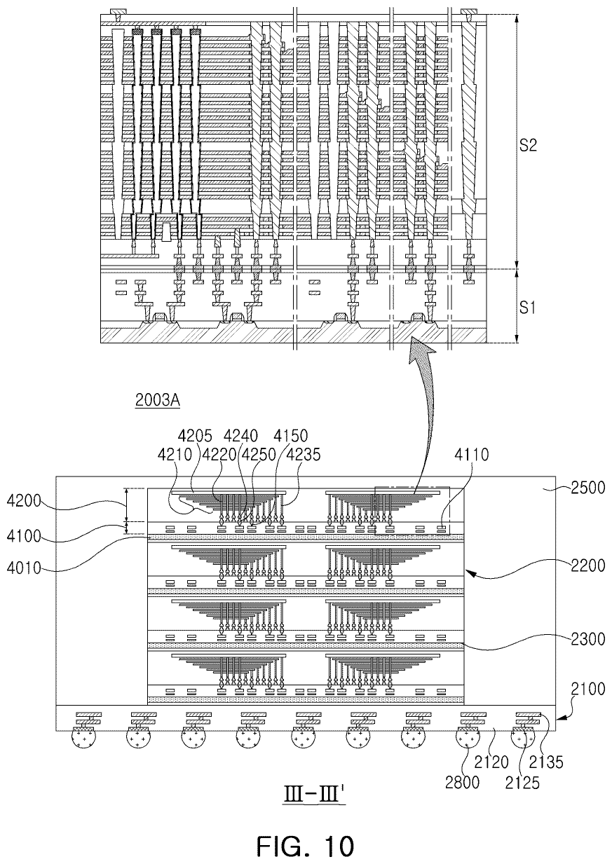

FIG. 10 is a cross-sectional diagram illustrating a semiconductor package according to various example embodiments, illustrating various example embodiments of the semiconductor package 2003 in FIG. 9 taken along line III-III′.

Referring to FIG. 10, in a semiconductor package 2003A, the package substrate 2100 may be implemented as a printed circuit substrate. The package substrate 2100 may include a package substrate body portion 2120, package upper pads 2130 disposed on an upper surface of the package substrate body portion 2120 (see FIG. 9), lower pads 2125 disposed on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main the substrate 2001 of the data storage system 2000 through the conductive connection portions 2800 as illustrated in FIG. 9.

Each of the semiconductor chips 2200 may include a first structure 3100 and a second structure 3200 sequentially stacked on the semiconductor substrate 3010 and the semiconductor substrate 3010. The first structure 3100 may include a peripheral circuit region including peripheral interconnections 3110. The second structure 3200 may include a common source line 3205, a gate stack structure 3210 on the common source line 3205, memory channel structures 3220 and isolation regions penetrating through the gate stack structure 3210, bit lines 3240 electrically connected to the memory channel structures 3220, and gate contact plugs 3235 electrically connected to wordlines (WL, see FIG. 8) of the gate stack structure 3210. As described above with reference to FIGS. 1 to 6, a plurality of gate electrodes 130 in each of the semiconductor chips 2200 may be commonly connected to the contact plug 170.

Each of the semiconductor chips 2200 may include a through interconnection 3245 electrically connected to peripheral interconnections 3110 of the first structure 3100 and extending into the second structure 3200. The through interconnection 3245 may be disposed on an external side of the gate stack structure 3210 and may be further disposed to penetrate through the gate stack structure 3210. Each of the semiconductor chips 2200 may further include an input/output pad 2210 (see FIG. 8) electrically connected to the peripheral interconnections 3110 of the first structure 3100.

According to the aforementioned example embodiments, in a structure in which two or more structures are bonded to each other, by including an insulating region extending from a back surface of the upper structure and penetrating through at least one lower gate electrode, and by configuring a slope direction of the channel structure to be opposite to a slope direction of the insulating region, a space for the insulating region may be secured or may be more likely to be secured, and accordingly, a semiconductor device having improved reliability and/or a data storage system including the same may be provided.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various example embodiments have been illustrated and described above, it will be configured as apparent to those skilled in the art that modifications and variations could be made without departing from the scope of inventive concepts as defined by the appended claims. Furthermore, example embodiments are not necessarily mutually exclusive. For example, some example embodiments may include one or more features described with reference to one or more figures, and may also include one or more other features described with reference to one or more other figures.

What is claimed is:

1. A semiconductor device, comprising:
a first semiconductor structure including a substrate, circuit devices on the substrate, and circuit interconnection lines on the circuit devices; and
a second semiconductor structure on the first semiconductor structure and having a first region and a second region,
wherein the second semiconductor structure includes:
a horizontal conductive layer;
gate electrodes stacked and spaced apart from each other in a first direction perpendicular to a lower surface of the horizontal conductive layer below the horizontal conductive layer, and including upper gate electrodes, memory gate electrodes, and lower gate electrodes, the upper gate electrodes, memory gate electrodes, and lower gate electrodes sequentially stacked from the horizontal conductive layer;
a horizontal connection portion disposed the memory gate electrodes and the lower gate electrodes;
channel structures in the first region penetrating through the gate electrodes and extending in the first direction;
isolation regions penetrating through the gate electrodes, extending in the first direction and in a second direction perpendicular to the first direction, and spaced apart from each other in a third direction perpendicular to the first and second directions;
an insulating region extending from a lowermost surface of the gate electrodes and penetrating through at least one of the lower gate electrodes between the isolation regions; and
second bonding metal layers below the gate electrodes and connected to the first bonding metal layers, wherein
an upper surface of the insulating region has a first width, and a lower surface of the insulating region has a second width greater than the first width, and
an upper surface of each of the channel structures has a third width, and a lower surface of each of the channel structures has a fourth width smaller than the third width.

2. The semiconductor device of claim 1, wherein each of the channel structures includes:
a first channel portion penetrating through the lower gate electrodes and extending in the first direction;
a connection channel portion penetrating through the horizontal connection portion and connected to the first channel portion; and
a second channel portion penetrating through the memory gate electrodes and the upper gate electrodes, extending in the first direction, and connected to the connection channel portion.

3. The semiconductor device of claim 2, wherein each of the channel structures includes:
a channel layer extending to the first channel portion, the connection channel portion, and the second channel portion; and
a gate dielectric layer extending to the first channel portion, the connection channel portion, and the second channel portion, and surrounding the channel layer.

4. The semiconductor device of claim 2, wherein a width of an upper surface of the first channel portion is greater than a width of a lower surface of the first channel portion.

5. The semiconductor device of claim 2, wherein the insulating region has a width increasing in a first direction, the increasing being with distance from the horizontal conductive layer, and the first channel portion has a width decreasing in the first direction, the decreasing being with distance from the horizontal conductive layer.

6. The semiconductor device of claim 2, wherein the insulating region is between the first channel portions of the channel structures adjacent to each other.

7. The semiconductor device of claim 2, wherein an upper surface of the insulating region is on a level lower than a level of a lower surface of the connection channel portion.

8. The semiconductor device of claim 2, wherein the horizontal connection portion includes:
connection gate electrodes stacked and spaced apart from each other in the first direction; and
interlayer insulating layers stacked alternately with the connection gate electrode.

9. The semiconductor device of claim 8, wherein the insulating region extends to penetrate through at least one of the connection gate electrodes.

10. The semiconductor device of claim 2, wherein
the second channel portion includes a first sub-channel portion and a second sub-channel portion sequentially stacked from the connection channel portion,
a width of an upper surface of the first sub-channel portion is greater than a width of a lower surface of the second sub-channel portion, and
a width of an upper surface of the connection channel portion is greater than a width of a lower surface of the first sub-channel portion.

11. The semiconductor device of claim 10, wherein
the second semiconductor structures further include interlayer insulating layers alternately stacked with the gate electrodes,
the memory gate electrodes, the upper gate electrodes, and the interlayer insulating layers form a first stack structure surrounding the first sub-channel portion and a second stack structure surrounding the second sub-channel portion, and
a thickness of the horizontal connection portion is greater than a thickness of the interlayer insulating layer between the first stack structure and the second stack structure.

12. The semiconductor device of claim 2, wherein a central line of a width of the second channel portion is collinear with a central line of a width of the connection channel portion and is not collinear with a central line of a width of the first channel portion.

13. The semiconductor device of claim 2, wherein a central line of a width of the connection channel portion is offset from a central line of a width of the second channel portion in the third direction, and a central line of a width of the first channel portion is offset from a central line of a width of the connection channel portion in the third direction.

14. A semiconductor device, comprising:
a horizontal conductive layer;
gate electrodes stacked and spaced apart from each other below the horizontal conductive layer in a first direction perpendicular to a lower surface of the horizontal conductive layer, and including upper gate electrodes, memory gate electrodes, and lower gate electrodes sequentially stacked from the horizontal conductive layer;
a horizontal connection portion between the memory gate electrodes and the lower gate electrode;
channel structures including a first channel portion penetrating through the lower gate electrode and extending in the first direction, a connection channel portion penetrating through the horizontal connection portion and connected to the first channel portion, and a second channel portion penetrating through the memory gate electrodes and upper gate electrodes and connected to the connection channel portion, and further including a channel layer connected to the first channel portion, the connection channel portion, and the second channel portion;
isolation regions penetrating through the gate electrodes and extending in the first direction and in a second direction perpendicular to the first direction, and spaced apart from each other in a third direction perpendicular to the first and second directions; and
an insulating region extending from a lowermost surface of the gate electrodes and penetrating through at least one of the lower gate electrodes between the isolation regions,
wherein a width of a lower surface of the insulating region is greater than a width of an upper surface of the insulating region, a width of a lower surface of the first channel portion is smaller than a width of an upper surface of the first channel portion, a width of a lower surface of the connection channel portion is smaller than a width of an upper surface of the connection channel portion, and a width of a lower surface of the second channel portion is smaller than a width of an upper surface of the second channel portion.

15. The semiconductor device of claim 14, wherein
the second channel portion includes a first sub-channel portion and a second sub-channel portions sequentially stacked from the connection channel portion, and
the first sub-channel portion and the second sub-channel portion have a width decreasing with distance from the horizontal conductive layer in the first direction.

16. The semiconductor device of claim 15, wherein
a width of an upper surface of the first sub-channel portion is greater than a width of a lower surface of the second sub-channel portion, and
a width of an upper surface of the connection channel portion is greater than a width of a lower surface of the first sub-channel portion.

17. The semiconductor device of claim 16, wherein a central line of a width of the first channel portion is offset from a central line of a width of the second channel portion in the third direction perpendicular to the second direction.

18. The semiconductor device of claim 17, wherein
a central line of a width of the connection channel portion is offset from a central line of a width of the second channel portion in a third direction perpendicular to the first direction, and a central line of a width of the first channel portion is offset from a central line of a width of the connection channel portion in the third direction, and
an upper surface of the insulating region is disposed on a level higher than a level of a lower surface of the connection channel portion.

19. A data storage system, comprising:
a semiconductor storage device including a first semiconductor structure including circuit devices, a second semiconductor structure disposed on one surface of the first semiconductor structure, and an input/output pad electrically connected to the circuit devices; and
a controller electrically connected to the semiconductor storage device through the input/output pad and configured to control the semiconductor storage device,
wherein the second semiconductor structure includes:
a horizontal conductive layer;
gate electrodes stacked and spaced apart from each other below the horizontal conductive layer in a first direction perpendicular to a lower surface of the horizontal conductive layer, and including upper gate electrodes, memory gate electrodes and lower gate electrodes sequentially stacked from the horizontal conductive layer;
a horizontal connection portion disposed between the memory gate electrodes and the lower gate electrodes;
channel structures penetrating through the gate electrodes and extending in the first direction in a first region;
isolation regions penetrating through the gate electrodes, extending in the first direction and a second direction perpendicular to the first direction, and spaced apart from each other in a third direction perpendicular to the first and second directions;
an insulating region extending from a lowermost surface of the gate electrodes and penetrating through at least one of the lower gate electrodes between the isolation regions; and
second bonding metal layers disposed below the gate electrodes and connected to the first bonding metal layers,
wherein an upper surface of the insulating region has a first width and a lower surface of the insulating region has a second width greater than the first width, and an upper surface of each of the channel structures has a third width and a lower surface of each of the channel structures has a fourth width less than the third width.

20. The data storage system of claim 19, wherein each of the channel structures includes a first channel portion penetrating through the lower gate electrode and extending in the first direction, a connection channel portion penetrating through the horizontal connection portion and connected to the first channel portion, a second channel portion penetrating through the memory gate electrodes and upper gate electrodes and connected to the connection channel portion, and further includes a channel layer connected to the first channel portion, the connection channel portion, and the second channel portion.
